(19) United States
(12) Patent Application Publication
(10) Pub. No.: US 2024/0193324 A1
(43) Pub. Date: Jun. 13, 2024

(54) SYSTEM AND METHOD FOR FINITE ELEMENT ANALYSIS IN THE PRESENCE OF CONCAVE ELEMENTS AND METHOD OF TESTING OR MANUFACTURING PRODUCTS USING SAME

(71) Applicant: Wisconsin Alumni Research Foundation, Madison, WI (US)

(72) Inventors: Krishnan Suresh, Madison, WI (US); Bhagyashree Chandrakant Prabhune, Madison, WI (US); Saketh Sridhara, Madison, WI (US)

(21) Appl. No.: 18/080,264

(22) Filed: Dec. 13, 2022

(51) Int. Cl. G06F 30/23; G06F 30/28

(52) U.S. Cl. CPC G06F 30/23; G06F 30/28

(57) ABSTRACT

A system and method for assessing a product or product design includes receiving a set of physical parameters and a mesh of finite elements of a product or product design. The mesh of finite elements include tangles. For elements in the mesh of finite elements, the method includes identifying positive and negative parametric regions. For tangled elements in the mesh of finite elements, the method includes relaxing a constraint of full invertibility between the positive and negative parametric regions to piecewise invertibility to decompose the tangled elements into invertible regions. The method further includes performing an analysis of the product or product design using the mesh of finite elements with the tangled elements decomposed into the invertible regions and the set of physical parameters and generating a report indicating a performance of the product or product design under the set of physical parameters.

### CROSS-REFERENCE TO RELATED APPLICATIONS

N/A

### STATEMENT REGARDING FEDERALLY SPONSORED RESEARCH N/A

### BACKGROUND

The present disclosure relates to systems and methods for product manufacturing, design, testing, forensic analysis, and the like. More particularly, the present disclosure relates to systems and methods for performing a finite element method (FEM) as part of a process, where the mesh created as part of the FEM includes one or more concave elements or, put another way, the mesh is tangled, yet the process can be performed with the resources and computational efficiency previously available only without the tangling. Thus, the underlying computer systems utilized are improved and more efficient than previously available and/or the process for manufacturing or analyzing the products using FEM are improved.

Traditional finite element methods (FEM) or analyses (FEA) are analysis techniques that allows a user to model and analyze systems by breaking the systems down into a finite number of simple problems. In FEM, the geometry of the proposed design is identified. The geometry is broken up into a discrete representation, known as a mesh or grid. The mesh is made up of a plurality of finite elements defined by simple polynomial shape functions, where the vertices of the shape define nodes. Boundary conditions (e.g. stress, constraints and/or loads) are applied to the mesh and the displacement of the elements is determined by the nodal displacements. Once the nodal displacements are known, element stresses and strains can be calculated. The governing equations are assembled into matrix form and are solved numerically.

FEM is often used by engineers and designers in new product design and in the refinement or forensic analysis of existing products. Using FEM, a user is able to verify a product design will perform in accordance with desired specifications prior to manufacturing or construction of such product. Thus, in many industries, such as the automobile or aircraft industries, all parts, subsystems, and whole systems are subjected to exhaustive FEM protocols as part of the manufacturing and design process.

Though FEM is an indispensable tool in countless industries, it is subject to some well-known limitations that have persisted despite efforts to overcome the limitations. For example, while FEM is a ubiquitous choice for solving boundary-value problems, a mesh must be created that meets several requirements before FEM can be utilized. One of the requirements is that, for every element of the mesh, the determinant of the Jacobian associated with the parametric mapping between the physical and parametric coordinates must remain positive. Said another way, the mesh must be free of concave elements or not be tangled.

If the determinant of the Jacobian is negative throughout an element, the element is said to be “fully inverted,” and the mesh is said to be “explicitly tangled.” An example of an explicitly tangled quadrilateral mesh is illustrated in FIG. 1a. If the determinant of the Jacobian is negative in parts of an element, the element is said to be partly inverted, and the mesh is said to be implicitly tangled. FIG. 1b illustrates an implicitly tangled quadrilateral mesh, with a concave element.

It is well known that tangled meshes can lead to erroneous results in FE simulations. As explained in M. Livesu, A. Sheffer, N. Vining, M. Tarini, Practical hex-mesh optimization via edge-cone rectification, ACM Transactions on Graphics (TOG) 34 (4) (2015) 1-11. “Even a single concave element makes a mesh unusable for simulation.” Unfortunately, tangling can appear, for example, during any of a variety of states of FEM, including mesh generation, mesh optimization, large deformation, and shape optimization.

In light of this, most FEM systems perform a check of meshes at various states to determine if there is a tangling. For example, if the determinant of the Jacobian is negative in any part of an element, the mesh is identified as tangled and the process must be revised or restarted, which is time consuming and complex.

In light of this substantial problem with tangling, various strategies have been proposed to address tangling. For example, “untangling” is perhaps the most common, which is where one attempts to modify the mesh to remove the concave element(s). However, untangling is not always possible/reliable and, often, one cannot determine whether untangling will be effective without undertaking the process. As described by P. M. Knupp, Hexahedral and tetrahedral mesh untangling, Engineering with Computers 17 (3) (2001) 261-268., “ . . . there are no known a priori test to determine if a mesh can be untangled.” Thus, untangling can be expensive, and can pose challenges in mapping of simulation data.

As such, others have proposed that a concave quad element can be split into triangle elements to remove the concave quad element. For example, this is undesirable in non-static applications, such as shape optimization and mesh morphing, where concave quad elements can appear/disappear at random locations.

Consequently, several approaches have been proposed for directly handling tangled elements. For example, in computer graphics, the method of invertible finite elements has been proposed, but this effort is focused on visual correctness, rather than on establishing accurate results as models for real-world physics.

For accurate analysis, non-traditional methods can potentially be used to handle concave quadrilateral elements. These include smoothed finite element (SFEM) polygonal finite element methods (PolyFEM) using mean value coordinates, generalized barycentric coordinates such as harmonic, and maximum-entropy coordinates. In addition, the virtual element method (VEM), where the element stiffness matrix can be computed without explicitly constructing the basis functions, have been used in particular situations to handle concave elements. However, these methods do not simplify to the well-established FEM when the quadrilateral mesh is non-tangled. Moreover, handling of explicit tangling has not been achieved using these methods.

Within the context of computational fluid dynamics (CFD), a strategy for handling zero and negative volume elements has been proposed where an edge-based discretization over triangle meshes was used. In this case, by explicitly accounting for signed-volume, one can handle tangled meshes, without a loss in accuracy. However, to deploy this method, an implicitly tangled quadrilateral mesh must be converted into a triangle mesh in order to maintain second-order accuracy, and this may not be desirable for reasons stated above, including computational efficiency.

Further still some have attempted to handle explicitly tangled simplex (triangular and tetrahedral) and non-simplex (quadrilateral) elements by performing a method that reduces to standard FEM when the mesh is regular, and in the case of tangling, additional correction terms are incorporated to the standard stiffness matrix. However, implicit tangling that is much more challenging than explicit tangling and, as such, was not addressed by such efforts.

Thus, there is a need for systems and methods that are able to efficiently address both explicitly and implicitly tangled two-dimensional (2D) and three-dimensional (3D) meshes, thereby applying to both quadrilateral and hexahedral elements.

### SUMMARY

The present disclosure provides systems and methods that overcome the aforementioned drawbacks by providing systems and methods for efficiently processing meshes, even in the presence of tangling, and irrespective of whether the mesh is an explicitly or implicitly tangled two-dimensional (2D) or three-dimensional (3D) mesh. That is, the systems and methods of the present disclosure break from the traditional paradigm that dictates that tangles cannot be accepted or, at best, cannot be processed with effectively the same computational overhead as without the tangles. Thus, the systems and methods of the present disclosure accept that tangles may be present because the systems and methods of the present disclosure are able to address tangles and still be computationally efficient.

In accordance with one aspect of the disclosure, a computer system is provided that includes a memory storing a mesh of finite elements of a product or product design, wherein the mesh of finite elements include tangles, an input configured to receive a set of physical parameters to be applied to the product or production design to assess the product or product design, and a processor. The processor is configured to receive the mesh of finite elements and the set of physical parameters and to carry out steps that include, for elements in the mesh of finite elements, identifying positive and negative parametric regions. The processor is further configured to carry out steps including, for tangled elements in the mesh of finite elements, relaxing a constraint of full invertibility between the positive and negative parametric regions to piecewise invertibility to decompose the tangled elements into invertible regions, performing an analysis of the product or product design using the mesh of finite elements with the tangled elements decomposed into the invertible regions and the set of physical parameters, and generating a report indicating a performance of the product or product design under the set of physical parameters. The computer system further includes a display or printer configured to deliver the report to a user.

In accordance with another aspect of the disclosure, a method for assessing a product or product design is provided that includes receiving a set of physical parameters to be applied to the product or production design, accessing a mesh of finite elements of a product or product design, wherein the mesh of finite elements include tangles, and, for elements in the mesh of finite elements, identifying positive and negative parametric regions. The method also includes, for tangled elements in the mesh of finite elements, relaxing a constraint of full invertibility between the positive and negative parametric regions to piecewise invertibility to decompose the tangled elements into invertible regions, performing an analysis of the product or product design using the mesh of finite elements with the tangled elements decomposed into the invertible regions and the set of physical parameters, and generating a report indicating a performance of the product or product design under the set of physical parameters.

In accordance with one other aspect of the disclosure, non-transitory computer-readable storage medium is provided having instructions stored thereon that, when executed by a computer processor, causes the computer process to carry out a method for analysis of a product or product design. The method includes steps comprising receiving a set of physical parameters and a mesh of elements of a product or product design, wherein the mesh of elements include tangles. The method also includes, for elements in the mesh of elements, identifying positive and negative parametric regions and, for tangled elements in the mesh of elements, relaxing a constraint of full invertibility between the positive and negative parametric regions to piecewise invertibility to decompose the tangled elements into invertible regions. The method further includes performing an analysis of the product or product design using the mesh of elements with the tangled elements decomposed into the invertible regions and the set of physical parameters and generating a report indicating a performance of the product or product design under the set of physical parameters.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A is an example of explicit tangling in a mesh.

FIG. 1B is an example of implicit tangling in a mesh.

FIG. 2A is an illustration of a concave quad in parametric space.

FIG. 2B is a is a mapping of the concave quad of FIG. 2A mapped onto physical space.

FIG. 2C is a is an illustration of the concave element of FIG. 2A and with the folded region.

FIG. 3A is an example of a two element mesh.

FIG. 3B is a graph showing L₂ error versus d for FEM.

FIG. 4A is a concave element shown with a 2D domain discretized into two bilinear quads.

FIG. 4B shows positive and negative Jacobian regions of the concave element of FIG. 4A.

FIG. 4C shows the convex element of the mesh of FIG. 4A.

FIG. 4D is an illustration of a physical space showing a self-overlapping region.

FIG. 5 is an illustration of FIG. 4D showing that equality conditions imposed at all concave vertices.

FIG. 6 is a graph showing a comparison of g-TFEM and FEM for two-element mesh: L₂ error vs. d.

FIG. 7 is a schematic illustrating parts contributing to the field definition.

FIG. 8A is an illustration of parametric space.

FIG. 8B is an illustration of a triangulation of a concave element.

FIG. 9 is a schematic illustrating numerical integration based on triangulation of the concave element.

FIG. 10A is a schematic showing g-TFEM involves integrating over the tangled region and concave region

FIG. 10B is a schematic showing i-TFEM involves integrating only over the concave region.

FIG. 11A shows an untangled hex element.

FIG. 11B shows a tangled hex element.

FIG. 12 shows the boundary of a negative Jacobian region.

FIG. 13 shows multiple views of a tetraheralized concave element.

FIG. 14 is an illustration of concave hexahedral element with two re-entrant vertices.

FIG. 15A is an illustration of a self-penetrating hexahedral element.

FIG. 15B is an illustration of an acceptable concave element obtained by moving a node.

FIG. 16A is a graph comparing i-TFEM and FEM for two-element mesh based on L₂ error vs. d.

FIG. 16B is a graph comparing i-TFEM and FEM for two-element mesh based on condition number vs. d.

FIG. 17 is an illustration of an implicitly tangled mesh with four elements.

FIG. 18A is a graph showing a comparison of i-TFEM and FEM for four-element mesh via error vs. α.

FIG. 18B is a graph showing a comparison of i-TFEM and FEM for four-element mesh via condition number vs. α.

FIG. 19A is a schematic illustration of a cantilevered product with parabolic loading.

FIG. 19B is a schematic illustration of the product of FIG. 19A as a mesh with concave elements.

FIG. 20 is a graph showing Error in u₂ for FEM and i-TFEM.

FIG. 21A is a graph showing σₓₓ for FEM and i-TFEM.

FIG. 21B is a graph showing τ_{xy} for FEM and i-TFEM.

FIG. 22 is a set of sample meshes for a convergence study with a number of nodes from 43 to 88 to 149 to 319.

FIG. 23A is a graph showing La norm errors for FEM and i-TFEM, as a function of the number of nodes.

FIG. 23B is a graph showing energy norm errors for FEM and i-TFEM, as a function of the number of nodes.

FIG. 24A is a graph showing σₓₓ at point B.

FIG. 24B is a graph showing u₂ at point C.

FIG. 25A is a schematic illustration of cross-section of a pressurized cylinder.

FIG. 25B is a typical mesh for the cylinder of FIG. 25A with concave elements.

FIG. 26 is a graphic illustration of sample meshes for convergence study, where the number of nodes and the number of concave elements were 77, 32; 163, 72; and 281, 128, respectively.

FIG. 27A is a graphs showing L₂ error norm as a function of number of nodes in a mesh for the pressurized cylinder of FIG. 25A.

FIG. 27B is a graphs showing CPU time as a function of number of concave elements in a mesh for the pressurized cylinder of FIG. 25A.

FIG. 28A is an illustration of an eight-element rectangular grid.

FIG. 28B is an illustration of an eight-element tangled mesh with a concave hex element.

FIG. 29A is a graph showing a comparison of L₂ error vs. d for i-TFEM and FEM for an eight-element hex mesh.

FIG. 29B is a graph showing a comparison of condition number vs. d for i-TFEM and FEM for an eight-element hex mesh.

FIG. 30 is a graphic illustration of a connecting rod mesh.

FIG. 31A is a color-coded illustration of the connecting rod mesh of FIG. 30 relative to a displacement analysis.

FIG. 31B is a color-coded illustration of the connecting rod mesh of FIG. 30 relative to a von-Mises stress field analysis.

FIG. 32A is a graphic representation of Cook's membrane problem.

FIG. 32B is a tangled mesh with one concave element.

FIG. 33A is an illustration of the concave element of FIG. 32B.

FIG. 33B is a graph of relative error in tip displacement versus d for FEM.

FIG. 34 is a graph of relative error in tip displacement versus d for FEM and i-TFEM.

FIG. 35A a graphic representation of an initial configuration for a regular mesh without any tangling for the Cook's membrane problem.

FIG. 35B is a graphic representation of a tangled mesh with N=3≡8×8 for the Cook's membrane problem.

FIG. 36 is a graph showing vertical displacement versus the load step for Cook's membrane problem.

FIG. 37A is a color-coded mapping of vertical displacement of a deformed configuration of the regular mesh of FIG. 35A.

FIG. 37B is a color-coded mapping of vertical displacement of a deformed configuration of the tangled mesh of FIG. 35B crated using i-TFEM.

FIG. 38 is a graph showing the results of a convergence study for Cook's membrane problem.

FIG. 39 is a graph showing H₁ error norm versus the number of nodes for Cook's membrane problem.

FIG. 40 is a graphic illustration of an initial configuration of the punch problem with mesh size N=2≡8×4 and the tangled mesh.

FIG. 41 is a graph showing vertical displacement versus the load step for the punch problem.

FIG. 42A is a color-coded mapping of vertical displacement of a deformed configuration for a regular mesh via FEM.

FIG. 42B is a color-coded mapping of vertical displacement of a deformed configuration for a tangled mesh via i-TFEM for the punch problem.

FIG. 43 is a graph showing the results of a convergence study for the punch problem.

FIG. 44 is a graph showing H₁ error norm versus the number of nodes for the punch problem.

FIG. 45 is a flow chart setting forth some non-limiting example steps of a method in accordance with the present disclosure.

FIG. 46 is a schematic illustration of a computer system that may be configured in accordance with the present disclosure.

### DETAILED DESCRIPTION

Finite element methods (FEM), sometimes referred to finite element analysis (FEA), and variations thereon, such as iso-geometric analysis (IGA), are essential to the designing, manufacturing, and testing (including forensic analysis) of modern products. Entire industries, such as the automobile or aircraft industry, could not exist in today's form if not for FEM and its variations, referred to hereafter as FEM. Products from medical devices to building components are designed, analyzed, manufactured, and tested using FEM.

However, as described above, tangled meshes in FEM present a substantial challenge in FEM. Even as computer systems have developed, incorporating improved processors and distributed processing environments using specialized processors like GPUs, tangled meshes cannot be handled in a computationally-efficient manner by modern computer systems. Thus, given the limitations of traditional FEM being performed on modern computer systems, inverted or concave elements (tangled meshes) can stop FEM in its tracks. Thus, tangles have generally required expensive efforts to remove the tangled mesh, either manhours to remove the concave elements or complex techniques to attempt to computationally remove the tangle, which can greatly increase processing time and is only successful in narrow situations.

The systems and methods of the present disclosure overcome these problems by improving the computer systems and methods, such that tangles are no longer a barrier in FEM, either a practical barrier or so computationally inefficient or costly as to be an effective barrier. The systems and methods of the present disclosure accept that tangles may be present because tangles they can still be computationally efficient.

### FEM Over Concave Elements

The above-described challenges with inverted or concave elements in FEM can be conceptualized mathematically. For illustrative purposes, the weak form for static elasticity problems can be considered:

Find u∈H, [symbol] ₀¹(Ω), such that ∀w∈ [symbol] ₀¹: (Ω),

$${\int }_{Ω} {( ∇ w )}^{T} D ( ∇ u ) d Ω = {\int }_{Ω} wbd Ω ; \qquad Eq . ( 1 )$$

where, ∇u denotes the symmetric part of displacement gradient while D is the material elasticity tensor and b is the body force. Recall that, in standard FEM, the underlying field at a point, p, belonging to the element Eⱼ is approximated using shape functions Eⱼ as follows:

u^{h}(p)=Nⱼ(p)ûⱼ Eq. (2)

Substituting Eq. 2 in the standard Galerkin form results in:

$$[ {\int }_{Ω} {( ∇ {\sum }_{j} {N}_{j} )}^{T} D ( ∇ {\sum }_{k} {N}_{k} ) d Ω ] \hat{u} = {\int }_{Ω} {( {\sum }_{j} {N}_{j} )}^{T} bd Ω ; \qquad Eq . ( 3 )$$

where û represent the global degrees of freedom. This leads to the linear system:

K⁰û=ƒ Eq. (4);

where,

$$\begin{matrix}{K}^{0} = {\prod }_{Assemble} {\int }_{{E}_{j}} ∇ {N}_{j}^{T} D ∇ {N}_{j} d Ω ; & Eq . ( 5 ) \\ f = {\prod }_{Assemble} {\int }_{{E}_{j}} ∇ {N}_{j}^{T} bd Ω . & Eq . ( 6 )\end{matrix}$$

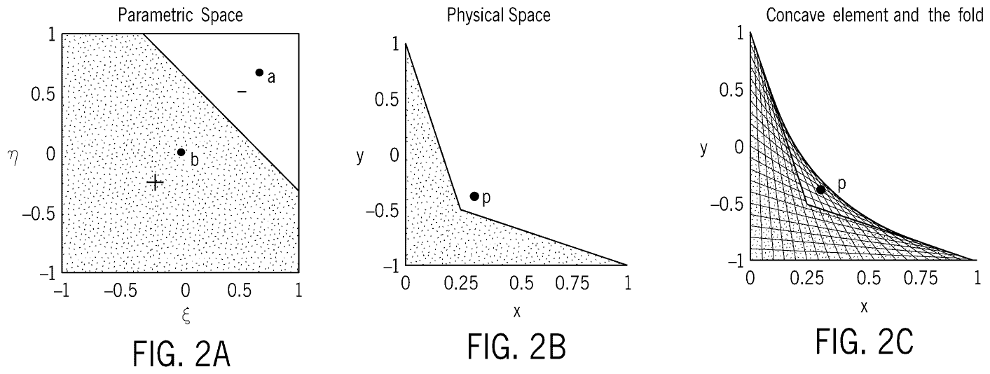

To compute Eq. 5 and Eq 6, one must rely on parametric mapping. Consider the standard parametric mapping from (ξ, η) space in FIG. 2A to the concave (partly inverted) element in the physical space (x, y) in FIG. 2B. For this particular concave element, one can show that the Jacobian | [symbol] | vanishes on the line 3ξ+3η=2, dividing the parametric space into a positive | [symbol] | region and a negative | [symbol] | region as illustrated in FIG. 2A. The corresponding curve in the physical space is quadratic, as shown in FIG. 2C.

Observe that parametric points such as a (ξ=⅔, η=⅔) and b (ξ=0, η=0) map to the same point p (x= 5/16, y= 5/16) that lies in the folded region. Therefore, the parametric mapping for a concave element is not fully invertible.

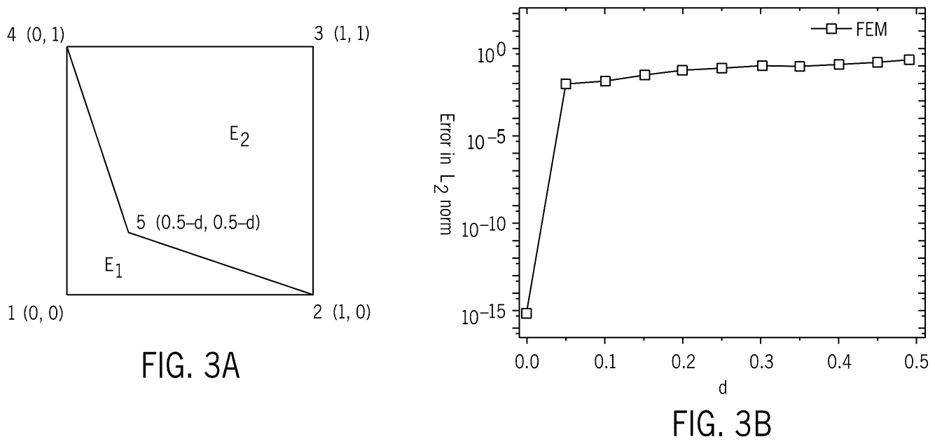

Next to illustrate the impact of a concave element on FEM, consider a mesh with just two elements, where one of the element is concave, as illustrated in FIG. 3A. A simple plane-stress elastostatics problem can be considered with Young's modulus E=1, Poisson's ratio ν=0.3, where the exact fields are given by:

u₁(x, y)=0.549x+0.264y+0.34, u₂(x, y)=0.486x+0.351y−0.62

Dirichlet boundary condition can be imposed on the left edge, and Neumann (traction) boundary conditions can be imposed on the remaining edges. For numerical integration, 9 quadrature points can be considered. Next, the position of node 5, as in FIG. 3A, can be varied, where d∈(0, 0.5). Observe that for all values 0<d<0.5, element E₁ is concave. For each value of d, one can solve for the two fields, using standard Gaussian integration to evaluate Eq. 5 and Eq 6. To measure the accuracy of FEM solution, L₂ error defined as follows can be employed:

$${‖ u - {u}^{h} ‖}_{{L}_{2} ( Ω )} = \sqrt{{\int }_{Ω} {( u - {u}^{h} )}^{2} d Ω} ; \qquad Eq . ( 7 )$$

where u and u^{h} are the exact and computed solutions respectively. FIG. 3B illustrates L₂ error-norm, i.e., FEM leads to erroneous results for 0<d<0.5.

Generalized Tangled FEM (g-TFEM)

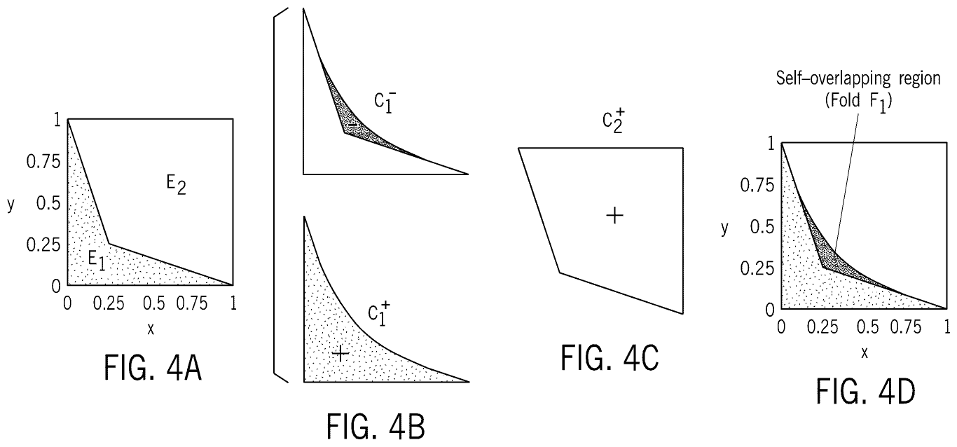

To address the above problem, a process referred to herein a generalized tangled FEM (g-TFEM) was developed. As will be described, g-TFEM handles the positive and negative parametric regions of the concave element separately, thus, relaxing the constraint of full invertibility to piecewise invertibility. Specifically, one can define the set of points in the physical space which maps from the positive (negative) | [symbol] | parametric region as positive (negative) component C₁⁺(C₁⁻), as illustrated in in FIG. 4A and FIG. 4B.

The concave element (E₁) can then be expressed as the difference between the two components:

E₁=C₁⁺−C₁⁻ Eq. (8).

On the other hand, the convex element E₂ has only the positive component:

E₂=C₂⁺; C₂⁻=Ø Eq. (9).

Observe that the components C₁⁺ and C₁⁻ overlap, and the overlapping region (tangled region) lies completely outside the physical boundaries of the element E₁. Further C₁⁻ also intersects with E₂. Thus, a concave quadrilateral element not only self-intersects, but also intersects the neighboring element(s).

Thus, any point in the implicitly tangled region can be interpreted as belonging to: (a) different parametric regions of the same element, and (b) multiple elements. Thus, fundamentally, the field is ambiguous in the tangled/folded region and Eq. 2 is invalid. Redefining the field over the tangled region achieved in g-TFEM.

To define the field unambiguously, g-TFEM recognizes the fact the parametric mapping is piecewise invertible. In other words, g-TFEM defines two shape functions N₁⁺ and N₁⁻ corresponding to Cⱼ⁺ and Cⱼ⁻, respectively. For example, for the point p=(x= 5/16, y= 5/16) in FIG. 2B, N₁⁺(p), are the shape functions of elements E₁ evaluated at (ξ=0, η=0) whereas N₁⁻(p) are the shape functions of element E₁ evaluated at (ξ=⅔, η=⅔). For the convex element, only N₂⁺ exists, while N₂⁺ is defined to be zero.

With these definitions, the field at any point p can be defined in g-TFEM as the oriented sum of the contributions from all components the point belongs to:

$${u}^{h} ( p ) ≡ {\sum }_{j \vert p ∈ {C}_{j}^{+}} {N}_{j}^{+} ( p ) {\hat{u}}_{j} - {\sum }_{j \vert p ∈ {C}_{j}^{+}} {N}_{j}^{-} ( p ) {\hat{u}}_{j} ; \qquad Eq . ( 10 )$$

Eq. 10 can be referred to as the unambiguity condition, that is, because the field is now unambiguously defined everywhere. For the above example, we have:

u^{h}(p)=N₁⁺(p)û₁−N₁⁻(p)û₁+N₂⁺(p)û₂ Eq (11).

Substituting this in the Galerkin formulation (for Eq. 1) results in:

$$K = {\int }_{Ω} {[ ∇ {\sum }_{j} ( {N}_{j}^{+} - {N}_{j}^{-} ) ]}^{T} D [ ∇ {\sum }_{k} ( {N}_{k}^{+} - {N}_{k}^{-} ) ] d Ω . \qquad Eq . ( 12 )$$

Regrouping leads to the stiffness matrix:

K=K⁰+K^{S}+K^{N} Eq. (13);

where:

$${K}^{0} = {\prod }_{Assemble} ( {\int }_{{C}_{j}^{+}} ∇ {N}_{j}^{{+}^{T}} D ∇ {N}_{j}^{+} d Ω + {\int }_{{C}_{j}^{-}} ∇ {N}_{j}^{{-}^{T}} D ∇ {N}_{j}^{-} d Ω ) \qquad Eq . ( 14 a )$$

$$\begin{matrix}{K}^{A} = {\prod }_{Assemble} ( - {\int }_{{C}_{j}^{+} ⋂ {C}_{j}^{-}} ∇ {N}_{j}^{{+}^{T}} D ∇ {N}_{j}^{+} d Ω - {\int }_{{C}_{j}^{+} ⋂ {C}_{j}^{-}} ∇ {N}_{j}^{{-}^{T}} D ∇ {N}_{j}^{-} d Ω ) & Eq . ( 14 b ) \\ {K}^{N} = {\prod }_{Assemble} ( - {\int }_{{C}_{j}^{+} ⋂ {C}_{k}^{+}} ∇ {N}_{j}^{{+}^{T}} D ∇ {N}_{k}^{+} d Ω - {\int }_{{C}_{j}^{-} ⋂ {C}_{k}^{+}} ∇ {N}_{j}^{{-}^{T}} D ∇ {N}_{k}^{+} d Ω - {\int }_{{C}_{j}^{+} ⋂ {C}_{k}^{-}} ∇ {N}_{j}^{{+}^{T}} D ∇ {N}_{k}^{-} d Ω + {\int }_{{C}_{j}^{-} ⋂ {C}_{k}^{-}} ∇ {N}_{j}^{{-}^{T}} D ∇ {N}_{k}^{-} d Ω ) . & Eq . ( 14 c )\end{matrix}$$

Observe that K⁰ is nothing but the classical stiffness matrix, while K^{S} and K^{N} are the correction terms. Similarly, the forcing term takes the form:

$${f}^{θ} = {\prod }_{Assemble} {\int }_{{C}_{j}^{+}} {N}_{j}^{{+}^{T}} b Ω - {\int }_{{C}_{j}^{-}} {N}_{j}^{{-}^{T}} b Ω . \qquad Eq . ( 15 )$$

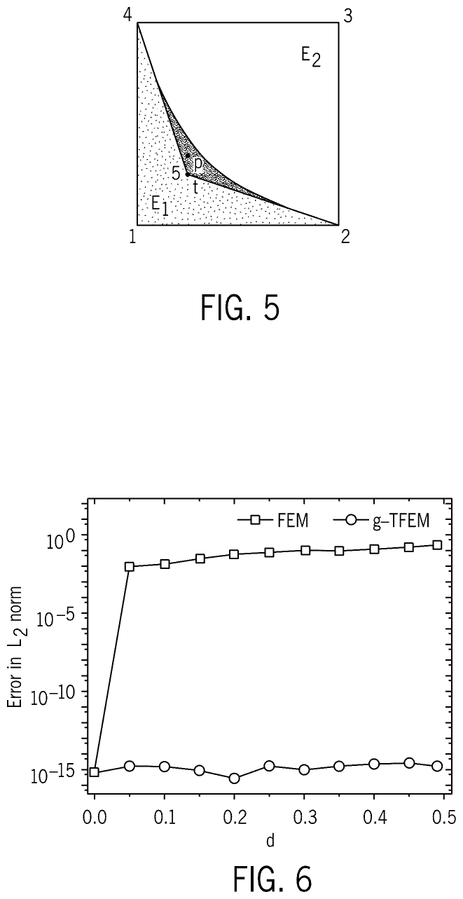

In addition, in g-TFEM, a piecewise compatibility constraint is needed at all re-entrant vertices to ensure compatibility. Consider a point, p, in FIG. 5. Since p belongs to three different components C₁⁺, C₁⁻, and C₂⁺, the field at point p is given by Eq. 11.

In the limit p→t, which represents the limit as p approaches the physical location corresponding to vertex v5, the last two terms in Eq. 11 cancel each other, resulting in:

u^{h}(t)=N₁⁺(t)û₁ Eq. (16);

that is:

u^{h}(t)=N₁¹⁺(t)u¹+N₁²⁺(t)u²+N₁³⁺(t)u⁵+N₁⁴⁺(t)u⁴ Eq. (17).

Here, the node numbers are denoted using superscripts while element numbers are denoted using subscripts. To be physically meaningful, u^{h}(t) must match the corresponding nodal value u⁵, resulting in:

N₁¹⁺(t)u¹+N₁²⁺(t)u²+N₁⁴⁺(t)u⁴+(N₁³⁺(t)−1)u⁵=0 Eq. (18);

where Eq. 18 is referred to here as the piecewise compatibility or equality condition that must be imposed at reentrant vertices of all concave elements in the mesh. This condition, together with the unambiguity condition, captures constant strain fields. The piecewise compatibility condition can be expressed as:

\tilde{C}û=0 Eq. (19);

where the number of rows in \tilde{C} is equal to the number of concave vertices times the degrees of freedom (DOF) per vertex. In summary, g-TFEM provides the frame work to then solve the following linear system of equations:

$$[ \begin{matrix}K & {\tilde{C}}^{T} \\ \tilde{C} & 0\end{matrix} ] \{ \begin{matrix}\hat{u} \\ μ\end{matrix} \} = \{ \begin{matrix}{f}^{θ} \\ 0\end{matrix} \} . \qquad Eq . ( 20 )$$

After solving Eq. 20, the unknown degrees of freedom û, along with the Lagrange multipliers μ are obtained. The Lagrange multipliers arise due to the finite set of constraint equations, and have no role in the field interpolation. Thus, g-TFEM is based on the field defined by Eq. 10 and the piecewise compatibility condition, satisfies the following conditions for convergence:
1. Continuity: The field is continuous within the element, and across element boundaries.
2. Rigid body: The element is strain free under rigid body (constant field) conditions (elasticity will be addressed later).
3. Constant strain: One can reproduce constant strain conditions exactly.

To illustrate, consider again the example discussed above regarding FEM over concave elements. That is, FIG. 6 confirms that g-TFEM leads to machine-precision accuracy for all the values of d.

Isoparametric TFEM (i-TFEM)

As described above, g-TFEM provides machine-precision accuracy for FEM over concave elements. However, to do so the g-TFEM formulation integrates over the fold to compute the correction terms. This can be programmatically difficult and computationally intensive. Moreover, care must be taken to avoid integration points very close to the | [symbol] |=0 curve. With this in mind the present disclosure provides further systems and methods, referred to herein as the isoparametric tangled finite element method (i-TFEM) that overcomes the programmatical challenges and computationally intensive processes that can result with g-TFEM.

For the two-element mesh in FIG. 5, with the coordinates of the nodes of element E₁ be denoted by \hat{x}=(x¹, x², x⁵, x⁴) and E₂, by \hat{x}₂=(x², x³, x⁴, x⁵). In isoparametric mapping, recall that, the spatial interpolation is the same as the field interpolation. Thus, for any point, p, inside the fold, by definition, Eq

x^{p}=N₁⁺(p)\hat{x}₁=N₁⁻(p)\hat{x}₁.

Further, since the formulation must reproduce a constant strain field, when u=x,

u^{h}(p)=N₁⁺(p)\hat{x}₁=N₁⁻(p)û₁ Eq. (21).

In other words, in an isoparametric formulation, the field value at any point within the fold must be the same independent of whether the positive or negative shape functions are used. The present disclosure recognizes this point and how to exploit this result to simplify the formulation.

As p→t (as shown in FIG. 5), N₁⁻(t)û₁=u⁵. Therefore, Eq. 21 can be rewritten in the form:

u^{h}(p)=N₁¹⁺(p)u¹+N₁²⁺(p)u²+N₁⁴⁺(p)u⁴+N₁³⁺(p)u⁵=u⁵ Eq. (22).

Now recall that the field at p within a fold is defined to be (as derived using Eq. 10):

u^{h}(p)=N₁⁺(p)û₁⁻N₁⁻(p)û₁+N₂⁺(p)û₂ Eq. (23).

Simplifying, yields:

u^{h}(p)=N₂⁺(p)û₂ Eq. (24).

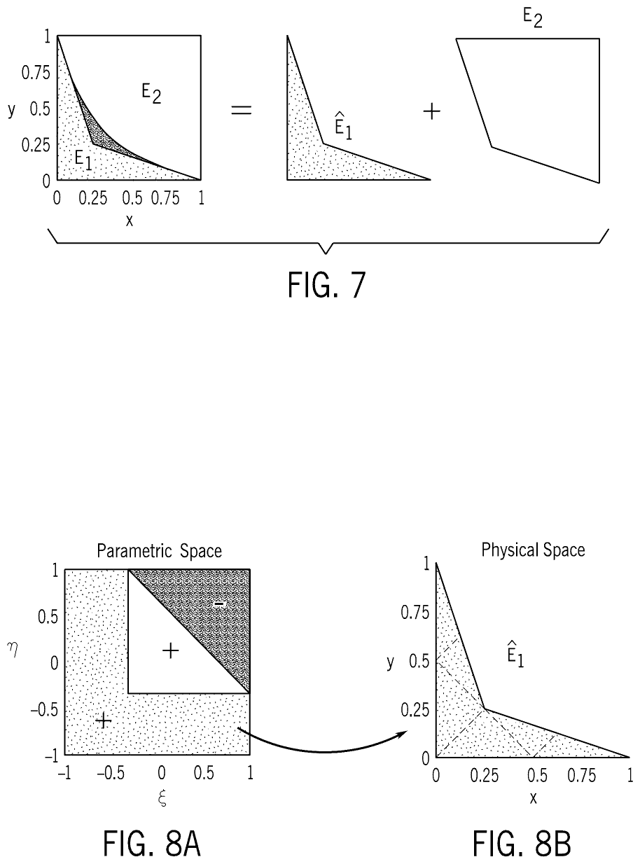

Thus, in an isoparametric element, the field at any point in the fold is the field defined by considering only the neighboring element E₂. Therefore, in i-TFEM, one can treat the fold as being part of the element E₂. Consequently, the mesh can be divided just into two parts: E₂ and Ê₁, as shown in FIG. 7. The contribution of E₂ to the stiffness matrix is given by the standard expression (the superscript ‘+’ is dropped henceforth from the shape functions for brevity):

$${k}_{2}^{0} = {\int }_{{E}_{2}} ( ∇ {N}_{2}^{T} D ∇ {N}_{2} ) d Ω . \qquad Eq . ( 25 )$$

This is the same as classical FEM, and standard Gauss quadrature schemes can be adopted. Next, consider the contribution of Ê₁ to the stiffness matrix. Note that the field in Ê₁ is given by:

u^{h}(p)=N₁⁺(p)û₁ Eq. (26).

Therefore, the stiffness matrix is given by (the superscript ‘+’ is dropped henceforth from the shape functions for brevity):

$${\hat{k}}_{1} = {\int }_{{\hat{E}}_{1}} ( ∇ {N}_{1}^{T} D ∇ {N}_{1} ) d Ω . \qquad Eq . ( 27 )$$

Observe that Ê₁ is not the same as E₁. Though both have the same physical boundary, they represent different regions of parametric space. Specifically, E₁ represents the entire parametric space while Ê₁ represents only a subset of positive | [symbol] | region as illustrated in FIG. 8A. Hence, standard Gauss quadrature scheme for quadrilateral elements cannot be used to evaluate \hat{k}₁. Instead, the concave region can be triangulated as in FIG. 8B for integration purposes.

In particular, a mesh may contain several concave elements, where a typical contribution, \hat{k}, due to a concave element Ê is given by:

$$\hat{k} = {\int }_{\hat{E}} ( ∇ {N}^{T} D ∇ N ) d Ω . \qquad Eq . ( 27 a )$$

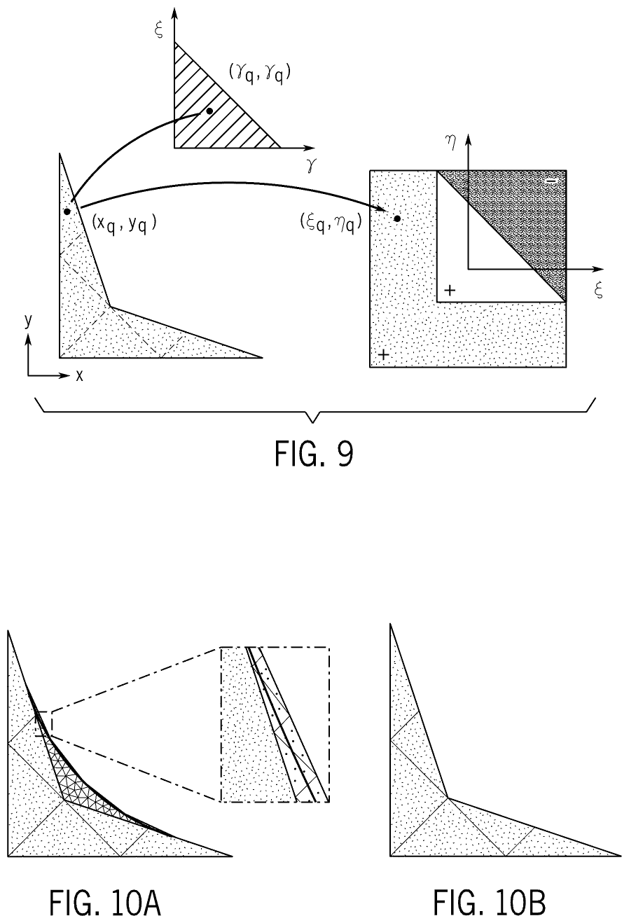

To evaluate the above expression, the above region Ê is triangulated as illustrated in FIG. 9, as:

$$\hat{k} = {\sum }_{triangles} {\int }_{triangle} ( ∇ {N}^{T} D ∇ N ) dxdy . \qquad Eq . ( 27 b )$$

Then each triangle, t, is mapped to a standard triangle in (γ, ζ)space, as illustrated in FIG. 9. In this case, |Jₜ| is the Jacobian associated with this triangle mapping. Thus, this gives:

$$\hat{k} = {\sum }_{t} {\int }_{0}^{1} {\int }_{0}^{1 - γ} ( ∇ {N}^{T} D ∇ N ) \vert {J}_{t} \vert d γ d ζ . \qquad Eq . ( 27 c )$$

Consider a quadrature point (γq, ζq) of the standard triangle with weight w_{q} as shown in FIG. 9. The corresponding point (xq, yq) in the physical space is shown in FIG. 9. Let (ξq, ηq) be the coordinates in the quadrilateral parametric space. This point can be numerically determined via Newton-Raphson algorithm. The Jacobian matrix (J_{q}) associated with the quadrilateral parametric mapping at these quadrature points. Let:

B_{q}=(J_{q})⁻¹∇_{ξη}N(ξ_{q}, η_{q}) Eq. (28).

Summing the contribution from all triangles results in:

$$\hat{k} = {\sum }_{t} {\sum }_{q} {( {B}_{q} )}^{T} D ( {B}_{q} ) \vert {J}_{t} \vert {w}_{q} . \qquad Eq . ( 29 )$$

Similarly, the forcing term f can be computed by integrating over Ê.

Moving to a global assembly, one can now assemble as follows:

$$\begin{matrix}{K}_{convex}^{0} = {\sum }_{Assemble - convex} {k}_{j}^{0} . & Eq . ( 30 ) \\ {\hat{K}}_{concave} = {\sum }_{Assemble - concave} {\hat{k}}_{j} . & Eq . ( 31 )\end{matrix}$$

The final global stiffness matrix for i-TFEM is then given by:

Kᵢₛₒ=K_{convex}⁰+\hat{K}_{concave} Eq. (32).

Similarly the forcing term is given by:

ƒᵢₛₒ=ƒ_{convex}⁰+\hat{ƒ}_{concave} Eq. (33);

where,

$$\begin{matrix}{f}_{convex}^{0} = {\prod }_{Assemble - convex} {f}_{j}^{0} ; \\ and & Eq . ( 34 ) \\ {\hat{f}}_{concave} = {\prod }_{Assemble - concave} {\hat{f}}_{j} . & Eq . ( 35 )\end{matrix}$$

Finally, the following linear system of equations can be solved for:

$$[ \begin{matrix}{K}_{iso} & {\tilde{C}}^{T} \\ \tilde{C} & 0\end{matrix} ] \{ \begin{matrix}\hat{u} \\ μ\end{matrix} \} = \{ \begin{matrix}{f}_{iso} \\ 0\end{matrix} \} ; \qquad Eq . ( 36 )$$

where the compatibility matrix \tilde{C} remains unchanged.

Observe that if the mesh does not contain any concave elements, only the terms corresponding to the convex elements (K_{convex}⁰ and ƒ_{convex}⁰) remain. Thus, i-TFEM reduces to the standard FEM for meshes without concave elements.

Comparing g-TFEM and i-TFEM, there are some appreciable distinctions. In g-TFEM, one must integrate over the tangled region and over the concave region, such as illustrated in FIG. 10A, and as described above. However, in i-TFEM, only the concave region, such as illustrated in FIG. 10B must be integrated over.

In order to integrate over the fold, g-TFEM triangulates the region, as shown in FIG. 10A. Further, to triangulate the fold, | [symbol] |=0 curve is approximated with sufficiently large number of segments. To illustrate, let the | [symbol] |=0 curve (highlighted) be approximated by four line segments, and the polygonal fold triangulated, as in FIG. 10A. Observe that the integration points for some of the triangles lie outside the folded region. This will lead to singularities, and therefore erroneous results. Hence, sufficiently large number of segments are employed to approximate | [symbol] |=0 curve leading to a large number of triangles. Thus, integrating over the fold is computationally expensive and programmatically complex, as described.

On the other hand, in i-TFEM, a small number of triangles can be employed to integrate over Êⱼ as shown in FIG. 10B, making i-TFEM computationally more efficient. This is demonstrated further following below. However, first, i-TFEM (and g-TFEM) can be readily extended to 3D applications.

### Extension to 3D

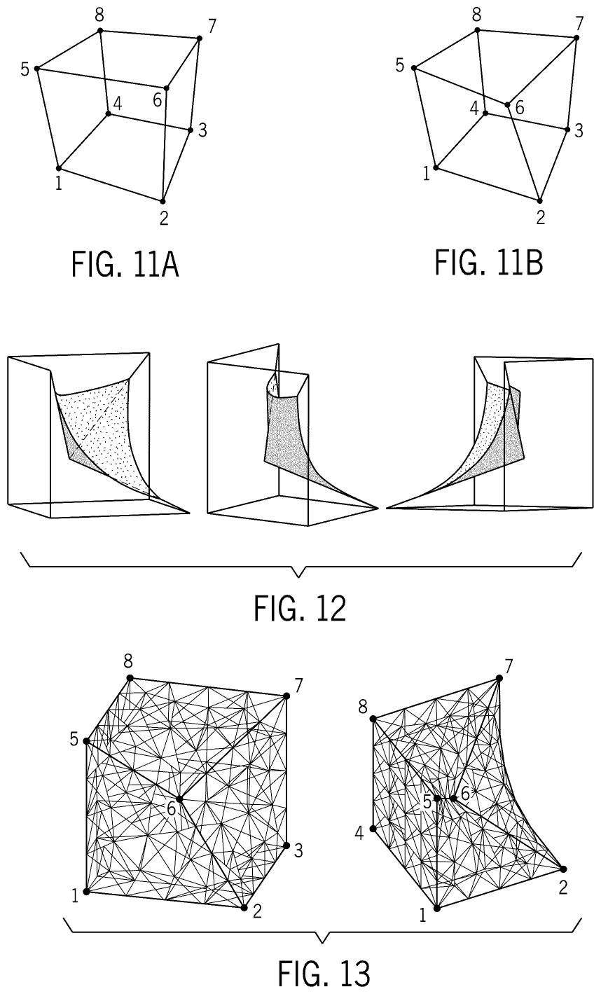

To apply the i-TFEM framework in 3D, consider a cononical 8-node hexahedral element, such as illustrated in FIG. 11A. If node 6 is moved diagonally towards node 4, as shown in FIG. 11B, it can become concave, i.e., tangled.

Different views of the corresponding tangled region are shown in FIG. 12. Observe that the tangled region is much more complex in 3D. Since i-TFEM avoids integration over such complex tangled regions, it is advantage over g-TFEM in such 3D situations.

The standard elemental stiffness matrices for convex 3D elements kⱼ⁰ are computed as in 2D. For a concave element, the stiffness matrix \hat{k}ⱼ is computed by tetrahedralizing the region Êⱼ as shown in FIG. 13. The contribution of each tetrahedron to \hat{k}ⱼ is computed by generalizing the procedure discussed above with respect to Eq. (27a) through Eq. (29).

However, unlike in a 2D application, Êⱼ is not a polyhedron. In general, the bounding surfaces are non-planar since there are four points that define each surface. Thus, they need to be approximately triangulated. Finer surface triangulation results in better approximation as illustrated below in the example experiments.

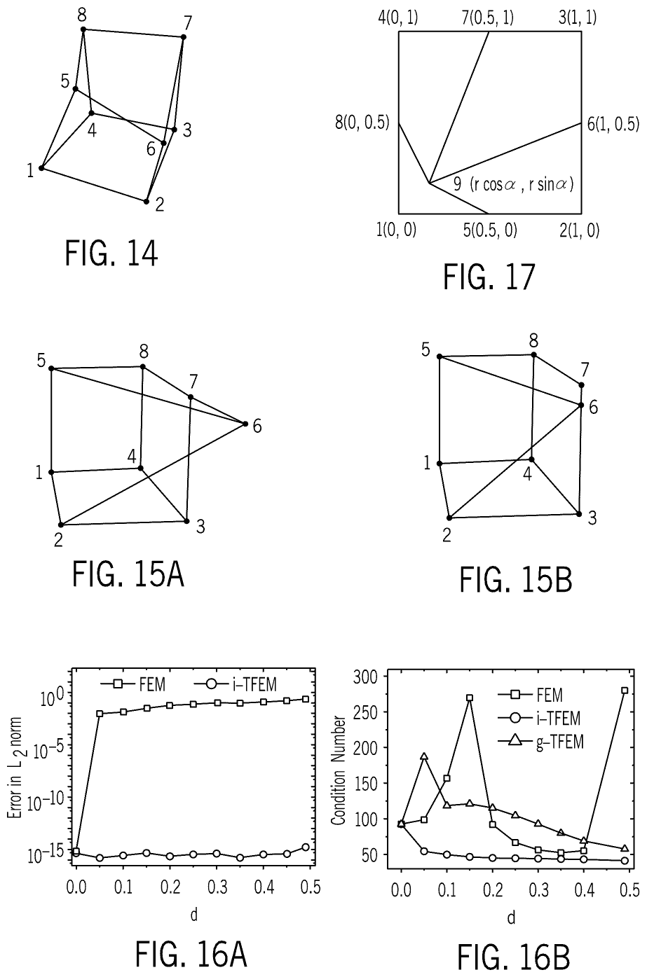

The final step in i-TFEM involves applying piecewise compatibility conditions. In 2D, a concave quadrilateral element has only one re-entrant vertex, and one constraint per DOF is applied at the re-entrant vertex. On the other hand, a concave hexahedral element can have more than one re-entrant vertex due to geometry as well as triangulations. For instance, the element in FIG. 14 has two re-entrant vertices (6 and 7). Further, the triangulation will induce several re-entrant vertices along the edge 5-6.

Hence, one cannot determine, a priori, the number of constraints per DOF in 3D. However, techniques can be used to determine the appropriate number of constraints. As one example, a technique based on the rank of the element stiffness matrix can be employed to determine the appropriate number of constraints per DOF as described below. First, a re-entrant vertex is identified. The piecewise compatibility conditions are computed at this vertex for all DOFs (such as using Eq. (21)), and these are appended to the elemental stiffness matrix \hat{k} or \hat{k}ⱼ. Next, the rows and columns corresponding to fixed DOFs are removed from the appended \hat{k}. The rank of the resultant matrix \hat{k} is then determined. If the matrix \hat{k} is full-ranked, the constraints are computed at another re-entrant vertex (or any other non-singular point) in the tangled region and appended to the matrix. Then the above step is repeated as long as the matrix \hat{k} remains full-ranked. Once the matrix becomes rank-deficient, the constraints associated with the latest point are removed. Thus, the number of piecewise compatibility conditions is the maximum number of conditions that result in a full ranked matrix. These conditions are then appended to the i-TFEM global stiffness matrix Kᵢₛₒ to form Eq. (36).

Thus, the fundamental changes in 3D i-TFEM relative to 3D g-TFEM include (1) in general, the surfaces of the concave elements are curved and can be approximated by piecewise triangles, and (2) the number of piecewise compatibility conditions required can be determined by examining the rank of the elemental stiffness matrix. Again this yields computational efficiency.

The above-described systems and methods are applied to tangled meshes that do not contain self-penetrating elements. A self-penetrating hexahedral element is shown in FIG. 15A. i-TFEM may be extended to such elements by perturbing the nodes such that the element can be processed in the current framework. For example, node-6 in FIG. 15A can be moved such that the element does not self-penetrate (but the element is still concave) as in FIG. 15B.

### Non-Limiting Example Experiments

A variety of numerical experiments were performed to demonstrate i-TFEM. Plane stress/strain problems in 2D and solid mechanics problems in 3D were solved over various tangled meshes. Numerical experiments were conducted under the following conditions. First, the implementation was in MATLAB R2021b, on a standard Windows 10 desktop with Intel(®) Core(™) 19-9820X CPU running at 3.3 GHz with 16 GB memory. The number of quadrature points for convex quadrilateral elements was 4, while 8 quadrature points were used for convex hexahedral elements unless otherwise stated. Next, in 2D, the triangulation of a concave element was performed by employing MATLAB's inbuilt mesher—generate Mesh. The number of quadrature points for triangles was 3. In 3D, tetrahedralization of concave elements are performed using Tetgen. The bounding surfaces were triangulated using generateMesh, and served as input to Tetgen. The surface mesh-size was set a relative size of ht=0.05, where ht was defined as the maximum allowable edge length of a surface triangle. The number of quadrature points for tetrahedrons was chosen to be 4.

The questions being investigated through the experiments were

Accuracy: How does the accuracy of i-TFEM compare against that of the FEM? Note that g-TFEM accuracy will match that of i-TFEM (but will be more expensive). To measure accuracy, we considered both the L2 error norm as defined in Eq. (7), and the energy error norm defined as:

$${{e}_{h} ‖}_{E ( θ )} = \sqrt{{\int }_{Ω} {( ϵ - {ϵ}^{h} )}^{T} D ( ϵ - {ϵ}^{h} ) d Ω} ; \qquad Eq . ( 37 )$$

where ϵ and ϵ^{h} are the exact and computed strain fields respectively.

Condition Number: How does the condition number of i-TFEM compare against FEM and g-TFEM? The condition number is a measure of a matrix's invertibility; it is desirable to have a condition number close to unity. To compute the 1-norm condition number, we employed MATLAB's built-in function condest.

Computational Cost: Is i-TFEM computationally more efficient than g-TFEM? MATLAB's built-in cputime function was employed to measure the computational cost.

Convergence: What is the convergence rate of i-TFEM and FEM as the element size decreases?

### 2D Patch Tests—Two Element Mesh

In the first experiment, we solved the problem discussed with respect to Eq. (8) through Eq. (20) using i-TFEM. FIG. 16A shows the L2 errors in FEM and i-TFEM, for varying degrees of tangling. i-TFEM achieved machine precision accuracy while classic FEM failed when the mesh gets tangled (g-TFEM matches the accuracy of i-TFEM but is harder/costlier to implement). On the other hand, the condition number of i-TFEM is lower than that of g-TFEM, as illustrated in FIG. 16B. This is because, in i-TFEM, integration over the regions close to the | [symbol] |=0 curve is avoided. The CPU time for FEM was 0.0406 seconds whereas, it was 0.0625 s and 1.0125 s for i-TFEM and g-TFEM, respectively.

### 2D Patch Tests—Four Element Mesh

Next a square domain Ω=(0, 1)×(0, 1) was considered, which was discretized into four quadrilateral elements, one of which is concave as in FIG. 17. The folded region was shared by three neighboring convex elements. To introduce asymmetry, move vertex 9 was moved along an arc of a circle as illustrated, where α varied from 15 degrees to 75 degrees and radius r=0.125√2.

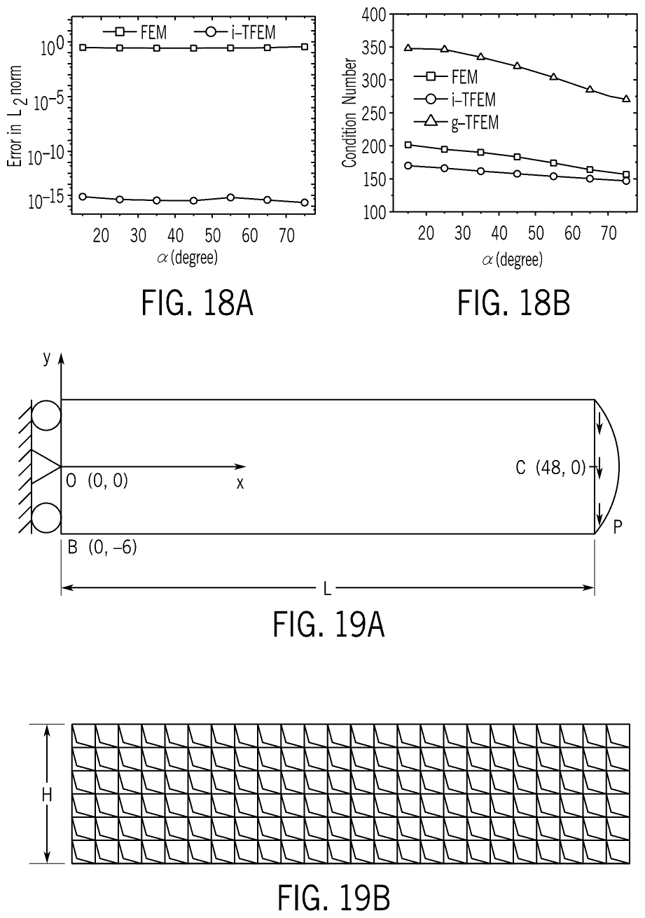

A plane stress elastostatics problem was solved with the displacement fields, elastic constants, and boundary conditions as in the two-element example considered earlier. FIG. 18A illustrates the L2 errors in FEM and i-TFEM, while FIG. 18B compares the condition numbers. As with the previous example, i-TFEM achieved machine precision accuracy while classic FEM failed. In terms of the condition number, i-TFEM again fared better than FEM and g-TFEM, as illustrated in FIG. 18B. Finally, FEM required 0.0257 s while i-TFEM and g-TFEM required 0.0335 s and 2.7902 s, receptively. Thus, i-TFEM outperformed g-TFEM in terms of speed and condition number.

### Cantilever Beam With Parabolic Loading

Consider a cantilever beam of length L=48 m, height H=12 m and a unit thickness subjected to a parabolic traction P=1000 N on the right edge, as illustrated in FIG. 19A. Assuming plane stress, the analytical solution is given by:

$$\begin{matrix}{u}_{1} = \frac{Py}{6 EI} [ ( 6 L - 3 x ) x + ( 2 + v ) ( {y}^{2} - \frac{{H}^{2}}{4} ) ] ; & Eq . ( 38 ) \\ {u}_{2} = \frac{P}{6 EI} [ ( L - x ) 3 {vy}^{2} + ( 4 + 5 v ) \frac{{H}^{2} v}{4} + ( 2 L - x ) {x}^{2} ] ; & Eq . ( 39 )\end{matrix}$$

where I=H³/12, E=3×10⁷ kPa and ν=0.3.

To solve this problem using finite elements, the domain is discrized to form a tangled mesh as shown in FIG. 19B and the boundary conditions are applied as shown in FIG. 19A. Here, the basic repeating unit is a 2-element mesh (such as illustrated in FIG. 3A) with d=0.4.

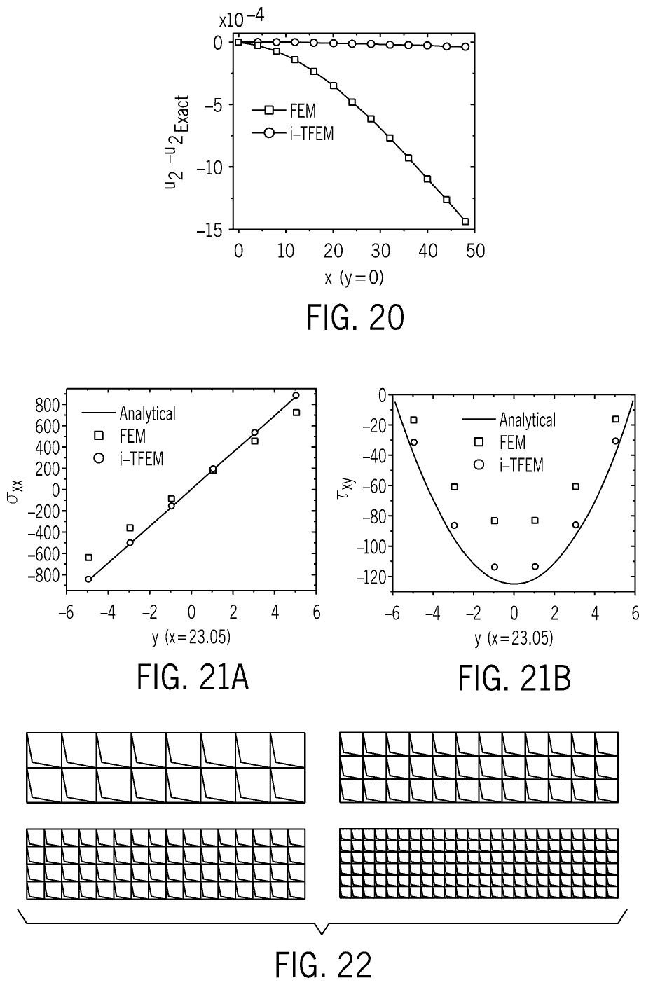

To evaluate the performance of FEM and i-TFEM, the error in the vertical displacement measured along y=0 was plotted, as illustrated in FIG. 20. FIG. 21 compares the stresses obtained using FEM and i-TFEM. Here, the stresses were measured at the element center along x=23.05. i-TFEM is more accurate than FEM, even when the exact solutions lie outside the span of the finite element space.

### Convergence

To study the convergence for the cantilever beam problem, various meshes were constructed as shown in FIG. 22. The basic repeating unit was the two-element mesh (see FIG. 3A) with d=0.4.

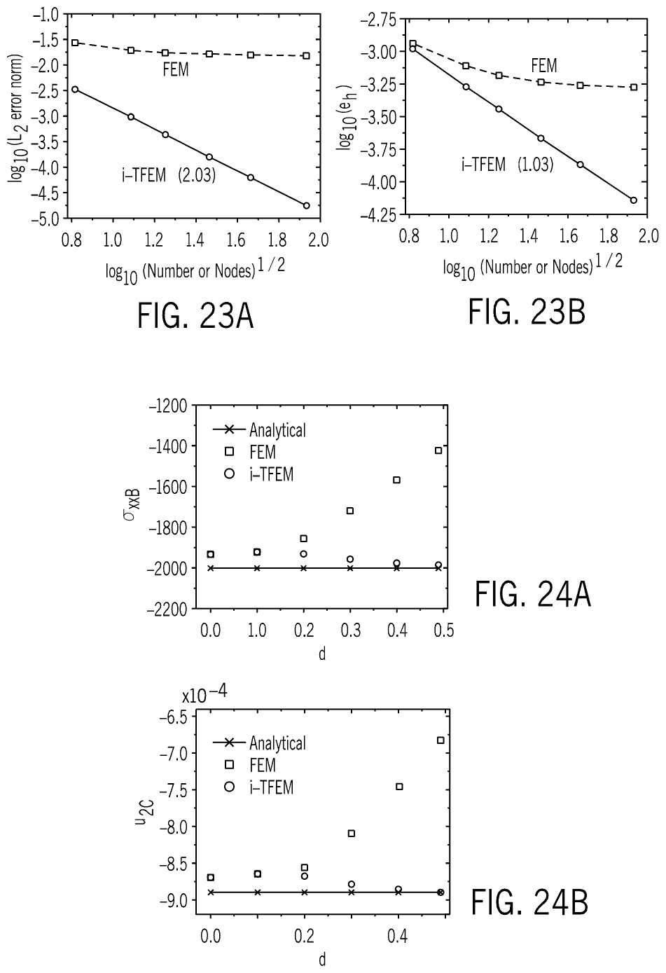

The L2 and energy norm errors for FEM and i-TFEM, as a function of the number of nodes, are illustrated in FIGS. 23A and 23B. For i-TFEM, the L2 and energy norm convergence rates were 2.03 and 1.03 respectively, i.e., they were optimal.

### Effect of Element Distortion

In the previous experiments, the extent of tangling was fixed with d=0.4. In this experiment, the effect of tangling on the computed solutions was considered by varying d from 0 to 0.49. In particular, we computed σₓₓ at the point B (located at the bottom left corner of the cantilever) and the vertical displacement u2 at point C (located on the right edge) in FIG. 19A.

When d=0, all quadrilaterals reduce to triangles and error is due to element distortion; i-TFEM reduces to FEM in this case. As d is increased, tangling increases and FEM error increases. On the other hand, i-TFEM error (mainly due to distortion) decreased as d increased, as illustrated in FIG. 24A and FIG. 24B.

### Pressurized Cylinder

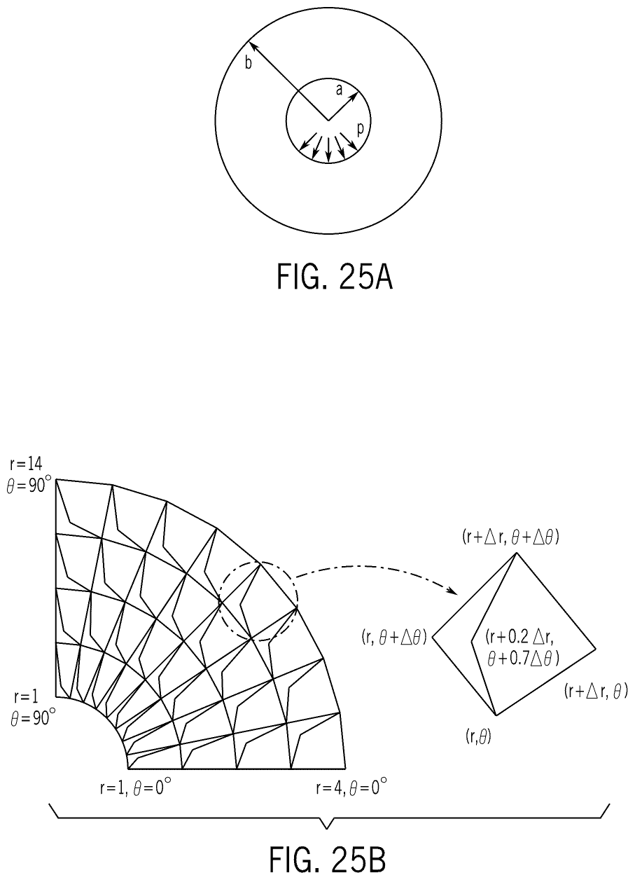

Consider a long hollow cylinder with internal radius a=1 and external radius b=4, such as illustrated in FIG. 25A. A uniform pressure p=1 is applied to the inner surface (r=a) and the cylinder deforms in plane strain. Let Poisson's ratio, ν=0.3 and Young's modulus, E=2.6. Due to the axisymmetric nature of the problem, only a quarter of the cylinder is modeled. The analytical solution is as follows:

$$u = \frac{p ( 1 + v ) {a}^{2} {b}^{2}}{E ( {b}^{2} - {a}^{2} )} ( \frac{1}{r} + \frac{r ( 1 - 2 v )}{{b}^{2}} ) {e}_{r} . \qquad Eq . ( 40 )$$

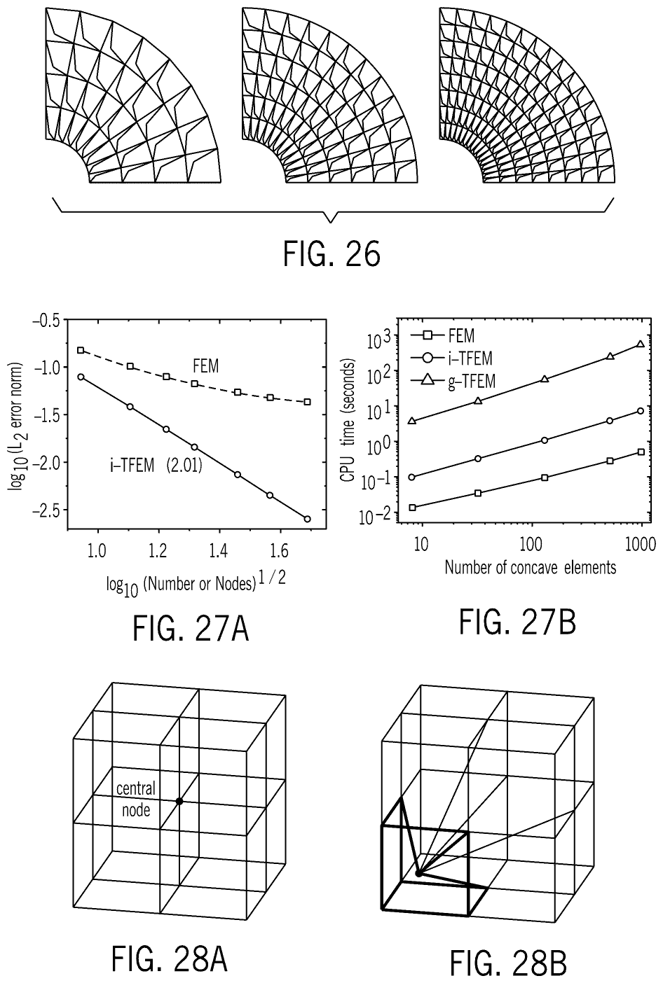

A typical mesh, shown in FIG. 25B, was constructed by using the two-element mesh as the basic repeating unit. To study the convergence behavior, various meshes were constructed as shown in FIG. 26.

FIG. 27A shows that i-TFEM leads to optimal convergence rate as opposed to FEM. Next, the CPU time for FEM, i-TFEM, and g-TFEM for various mesh sizes was analyzed. FIG. 27B shows that i-TFEM is much faster than g-TFEM. FEM can be the fastest, but is inaccurate. Note that for the meshes of FIG. 26 that were used, there are equal number of concave and convex elements. However, in practical scenarios, this is rarely the case since the number of concave elements will be much smaller compared to the convex elements. Therefore, the additional cost incurred by i-TFEM will be minimal in a real-world situation where there are limited convex elements.

### 3D Patch Test: Eight-Element Hex Mesh

A cubic domain Ω=(0, 2)×(0, 2)×(0, 2) was also considered. The domain was discretized into eight hexahedral elements, as shown in FIG. 28A. For the regular (untangled) mesh, the central node was located at (1, 1, 1). To demonstrate TFEM, the central node was moved so that one becomes concave as shown in FIG. 28B. Note that the concave element has only one re-entrant vertex. To vary the extent of tangling, the central node was given as: (1, 1, 1)−d×(1, 0.95, 0.98) where the parameter d∈(0, 0.9). For d=0, the mesh is the regular grid as shown in FIG. 28A.

The material parameters were E=1, and ν=0.3. The exact displacement field u was:
u₁=0.579 x+0.246 y+0.482 z−0.374
u₂=0.486 x+0.351 y+0.947 z−0.62
u₃=0.512 x+0.746 y+0.548 z−0.48

The corresponding Dirichlet boundary conditions were applied on the left surface, while Neumann conditions were applied on the remaining surfaces. As shown in FIG. 29A, i-TFEM was significantly more accurate than FEM. Recall that the accuracy of i-TFEM in 3D depends on how well the bounding surfaces of the concave element are approximated via surface triangulations. To study the effect of surface-mesh size on the i-TFEM accuracy, three were considered: hₜ=0.035, 0.007, and, 0.005. Here, hₜ indicates the maximum edge length of triangles. Finer surface triangulation results in better accuracy of i-TFEM solution as illustrated in FIG. 29A. For hₜ=0.005, i-TFEM is 1010 times more accurate than FEM. FIG. 29B compares the condition number for FEM and i-TFEM (for all values of hₜ).

### Application: Connecting Rod

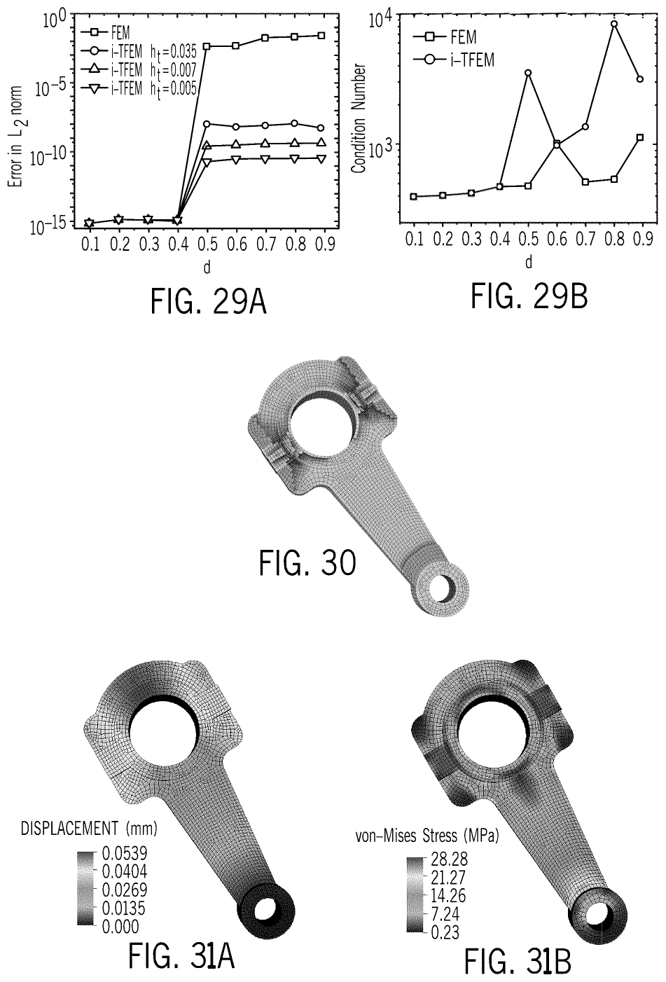

A connecting rod mesh, as illustrated in FIG. 30, was considered. The units were in cm. The mesh contained 14783 nodes and 11316 hexahedral elements, out of which 16 elements were concave. Some of the elements were self-penetrating. Therefore, the nodes were perturbed such that the elements do not self-penetrate. An axial load P=300N was applied on the upper half region of the larger end, while the smaller end was fixed. The material properties were as follows: the Young's modulus E=1.1×10⁵ MPa and the Poisson's ratio ν=0.35.

Then i-TFEM was employed to carry out the linear quasi-static structural analysis. The resultant displacement field is shown in FIG. 31A, while the von-Mises stress field is plotted in FIG. 31B. The total computational time was 18.742 s, out of which, 1.7 s was spent processing the concave elements, i.e., the overhead due to i-TFEM was found to be minimal.

### Nonlinear Elasticity

The above-described systems and methods can be utilized in situations with compressible nonlinear elasticity. Consider a body occupying domain Ω∈R² subject to a body force b and traction T undergoing a large-deformation u, where the material is assumed to be hyper-elastic. The potential energy of this system can be written as:

$$\prod ( u ) = {\int }_{Ω} Ψ ( F ( u ) ) dV - {\int }_{Ω} Ψ \cdot bdV - {\int }_{\partial {Ω}_{h}} u \cdot TdS ; \qquad Eq . ( 41 )$$

where F is the deformation gradient and Φ is the strain energy density. Further, using the standard (Bubnov-) Galerkin variational formulation, one arrives at the residual equation:

R(û)=0 Eq. (42);

that is typically solved iteratively via Newton-Raphson algorithm:

K(ûⁿ)Δûⁿ⁺¹=−R(ûⁿ) Eq. (43);

where K is the tangent matrix and ûⁿ is the incremental displacement vector at nth Newton iteration. When the mesh is of high-quality and not tangled, one obtains accurate solutions to such problems. However, as is well known, when the mesh is tangled, the solution becomes erroneous.

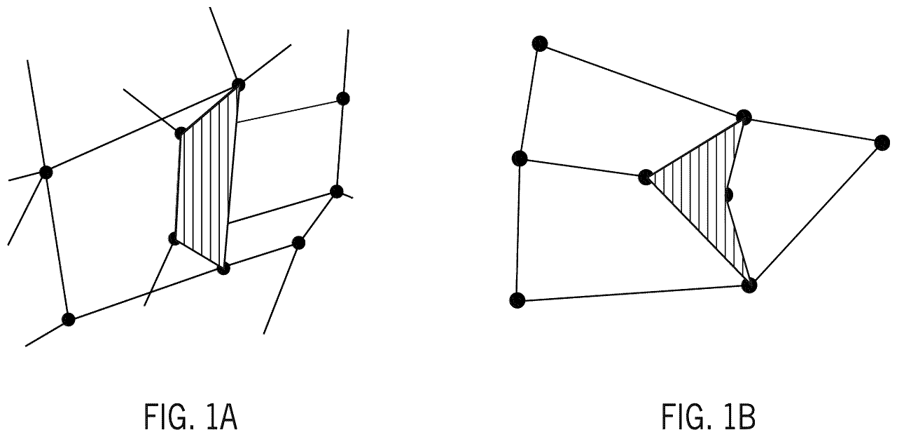

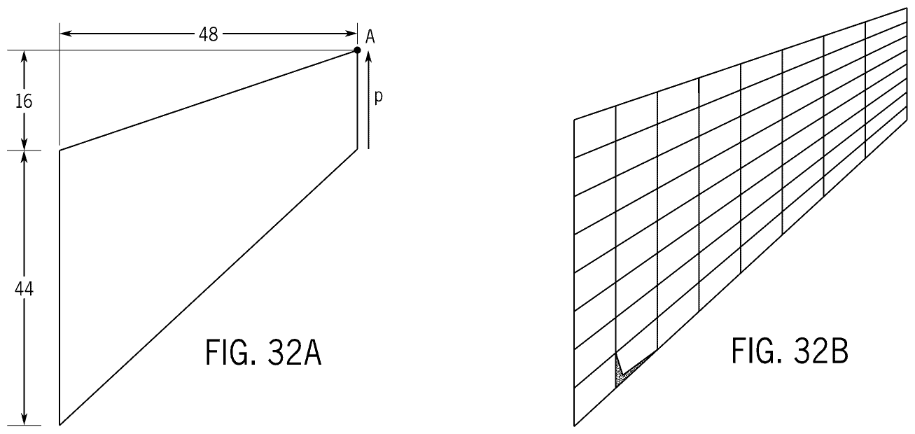

To illustrate, consider the Cook's membrane problem illustrated in FIG. 32A. The left edge of the tapered cantilever is fixed while a uniformly distributed load p=5 is applied on the right edge. A geometrically nonlinear plane-strain problem with Lamé parameters μ=50 and λ=100 in FIG. 1B illustrates a quadrilateral mesh with one concave element that was experimentally utilized.

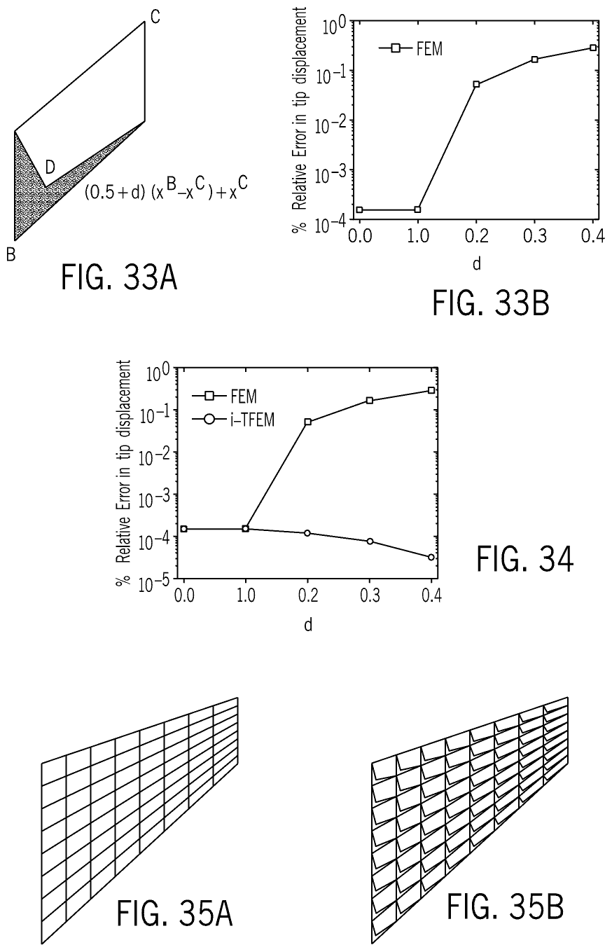

The extent of tangling was varied by moving the re-entrant vertex D along the diagonal BC as shown in FIG. 33A. When the parameter d=0, the point D lies half-way between B and C, and when 0<d<0.5, the point D moves towards B, i.e., the element gets tangled. The large-deformation problem can be solved using the normal procedure as described above, with 10 load steps. The tip displacement was compared against the expected value (using a high quality non-tangled mesh). When d>0.1, a negative |z,57 | value is encountered at one or more Gauss points, and FIG. 33B illustrates the resulting erroneous solution.

Applying i-TFEM to non-linear elasticity can be shown by generalizing the residual in Eq. 42 and the iteration in Eq. 43. Towards this end and going back to FIGS. 4A-4D, Eq. (10) can be simplified toward the example as:

u(p)=u₁⁺−u₁⁻+u₂⁺ Eq. (43).

This can be rewritten with the assumption that the element is iso-parametric. Thus, for optimal convergence, an additional compatibility condition must also be satisfied:

u₁⁺(p)−u₁⁻(p)=0, ∀p∈F₁ Eq. (45).

From Eq. 43 and Eq. 45, this gives:

u(p)=u₂⁺(p), ∀p∈F₁ Eq. (46).

In other words, for iso-parametric elements, the tangled region can be considered as being part of just E₂, as described above. Again, this naturally leads to division of the mesh into two parts: E₂ and Ê₁ as illustrated in FIG. 5. That is, the tangled region for iso-parametric elements can be disregarded. In summary, for any pair of tangled elements E₁ and E₂, they can be decomposed into fully invertible regions Ê₁ and E₂. For stiffness matrix computations, only the parametric region corresponding to Ê₁ is considered. The constraint equation (Eq. 45) is imposed at reentrant vertices.

The constraints in Eq. 45 can be incorporated directly into the potential energy in Eq (41) as follow:

$$\tilde{\prod } ( u ) = {\int }_{{\hat{E}}_{1}} ( Ψ ( {u}_{1} ) - i = {u}_{1} \cdot b ) dV + {\int }_{{E}_{2}} ( Ψ ( {u}_{2} ) - {u}_{2} \cdot b ) dV - {\int }_{\partial {E}_{h 1}} {u}_{1} \cdot TdS - {\int }_{\partial {E}_{h 2}} {u}_{2} \cdot TdS + {\int }_{{F}_{1}} λ ( {u}_{1}^{+} - {u}_{1}^{-} ) dV ; \qquad Eq . ( 47 )$$

where an additional term is included to account for the piecewise compatibility, and λ are the corresponding Lagrange multipliers. Observe that, given several concave elements Eⱼ associated with tangled regions Fⱼ, the potential energy can be generalized to:

$$\tilde{\prod } ( u ) = {\int }_{Ω} Ψ ( u ) dV - {\int }_{Ω} u \cdot bdV - {\int }_{\partial {Ω}_{h}} u \cdot TdS + {\sum }_{j} {\int }_{{F}_{j}} λ ( {u}_{j}^{+} - {u}_{j}^{-} ) dV . \qquad Eq . ( 48 )$$

Now the variation of the potential energy with respect to u and λ can be set to zero:

δ_{u,λ}\tilde{Π}=0 Eq. (49);

that is,

$$\frac{d}{d ∈} \tilde{\prod } ( u + ∈ δ u , λ + ∈ δλ ) {\vert}_{ϵ = 0} = 0. \qquad Eq . ( 50 )$$

This leads to the following weak form:

$$\underbrace{{\int }_{Ω} ( P : \frac{\partial δ u}{\partial X} - δ u \cdot b ) dV - {\int }_{\partial {Ω}_{h}} δ u \cdot TdS + {\sum }_{j} {\int }_{{F}_{i}} λ \cdot ( δ {u}_{j}^{+} - δ {u}_{j}^{-} ) dV}_{δ {\hat{u}}^{T} \tilde{R}} + \underbrace{{\sum }_{j} {\int }_{{F}_{j}} δλ \cdot ( {u}_{j}^{+} - {u}_{j}^{-} ) dV}_{δ {\hat{λ}}^{T} {C}^{T} \hat{u}} = 0. \qquad Eq . ( 51 )$$

Next, the fields can be approximated using the standard (Bubnov-) Galerkin formulation as:

uⱼ≈Nⱼûⱼ, uⱼ⁺≈Nⱼ⁺ûⱼ, uⱼ⁻≈Nⱼ⁻ûⱼ, λ≈N^{λ}\hat{λ} Eq. (52);

where N^{λ}=1 for simplicity. This leads to:

δû^{T}\tilde{R}+δ\hat{λ}^{T}C^{T}û=0 Eq. (53).

Observe from Eq. (51) that the residual \tilde{R} can be expressed as:

\tilde{R}(û, \hat{λ})=R^{u}(û)+C\hat{λ}=0 Eq. (54);

where R^{u} is a function of û alone and involves integrating over convex and concave elements:

T^{u}=R_{convex}^{u}+\hat{R}_{concave}^{u} Eq. (55).

The computation of R_{convex}^{u} is as in standard FEM. However, recall that the integration over the concave elements must be carried out over the subset of parametric space (see FIGS. 8A and 8B and accompany discussion). To solve Eq. (54) through iterations, consider the first order Taylor series:

$${R}^{u} ( {\hat{u}}^{n} ) + \frac{\partial {R}^{u}}{\partial \hat{u}} {\vert}_{n} Δ {\hat{u}}^{n + 1} + C {\hat{λ}}^{n} + C Δ {\hat{λ}}^{n + 1} = 0 ; \qquad Eq . ( 56 )$$

that is,

K^{t}Δû+CΔ\hat{λ}=−(R^{u}+C\hat{λ}) Eq. (57);

where

K^{t}=K_{convex}^{t}+\hat{K}_{concave}^{t} Eq. (58).

Here, K_{convex}^{t} and \hat{K}_{concave}^{t} are tangent matrices corresponding to convex and concave elements respectively. Further, from Eq. (53), we have

C^{T}Δû=0 Eq. (59).

From Eq. (57) and Eq. (59), the final set of linear equations one must solve iteratively is:

$$[ \begin{matrix}{K}^{t} & C \\ {C}^{T} & 0\end{matrix} ] \{ \begin{matrix}Δ {\hat{u}}^{n + 1} \\ Δ {\hat{λ}}^{n + 1}\end{matrix} \} = \{ \begin{matrix}- ( {R}^{u} + C \hat{λ} ) \\ 0\end{matrix} \} . \qquad Eq . ( 60 )$$

Again, if the mesh does not contain any tangled elements, i-TFEM reduces to standard FEM. To compute R_{convex}^{u} in Eq. (55), standard FEM procedures with Gauss quadrature can be used. However, to compute R_{concave}^{u}, only the fully invertible subset of parametric space Ê₁ is considered. Therefore, standard Gauss quadrature cannot be employed. Instead, as described above with respect to FIG. 8B, Ê₁ can be triangulated. The triangulation is used merely for the purpose of integration and does not lead to additional degrees of freedom in i-TFEM.

Similarly, to compute K_{convex}^{t}, standard FEM procedures can be used. However, to compute K_{concave}^{t}, the triangulation in FIG. 8B is used. Finally, to computer the constraint matrix, C, not that:

$$C = {\int }_{{F}_{1}} {( {N}_{1}^{+} - {N}_{1}^{-} )}^{T} dV . \qquad Eq . ( 61 )$$

Direct integration over the tangled region F₁ is computationally expensive, and may lead to singularities. Since N^{λ} is unity, it is sufficient to evaluate the integrand at a single point. Therefore, C can be evaluated the at the re-entrant vertex.

### Numerical Experiments

i-TFEM was demonstrated using plane strain nonlinear elasticity problems over various tangled meshes. Numerical experiments were conducted under the following conditions. First, the implementation is in MATLAB R2020b, on a standard Windows 10 desktop with Intel(®) Core(™) i9-9820X CPU running at 3.3 GHz with 16 GB memory. Next, the number of quadrature points for convex quadrilateral elements is 4 unless otherwise stated. Further, the triangulation of a concave element is performed by employing MATLAB's inbuilt mesher—generateMesh. The number of quadrature points for triangles was 3. Finally, the load was applied incrementally in 10 steps. The stopping criteria for Newton Raphson was ∥Δû∥<10⁻⁹.

Through the experiments, the following were investigated:

Cook's problem, single concave element: For Cook's membrane problem, the error in tip displacement due to the presence of a single concave element is reported as the severity of tangling is increased.

Cook's problem, multiple concave elements: For Cook's membrane problem, with numerous tangled elements: (a) The displacement at a prescribed location is reported for each load step. (b) Deformed configurations for tangled and regular meshes are also compared. (c) Convergence of the tip displacement as a function of mesh size is studied and compared against standard FEM. (d) Finally, the convergence rate is evaluated.

Punch problem, material non-linearity: For a punch problem [24], we include material nonlinearity and study the convergence characteristics of i-TFEM.

### 2D Cook's Membrane: Single Concave Element

To begin , the Cook's membrane problem was solved over the mesh with one concave element illustrated earlier in FIG. 32B. Recall that the extent of tangling is controlled by the parameter d. For d>0.1, a sharp increase in FEM error was observed, as illustrated in FIG. 34. On the other hand, using i-TFEM, the error, in fact, slightly decreased for d>0.1, as illustrated in FIG. 34.

### 2D Cook's Membrane: Multiple Concave Elements

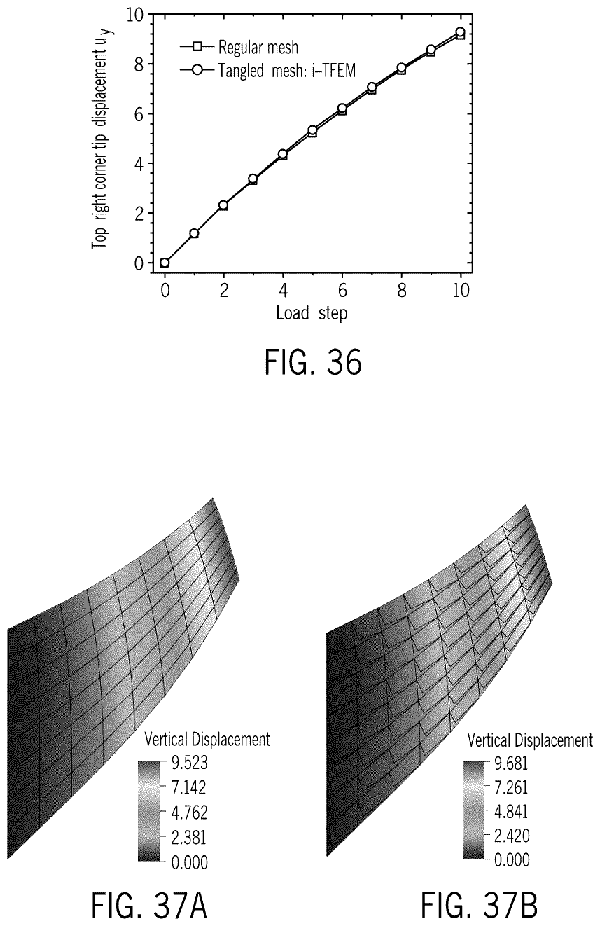

Next, a regular mesh, illustrated in FIG. 35A, and a highly tangled mesh in FIG. 35B where every other element is concave were considered. The Cook's membrane problem was solved over the regular mesh using standard FEM, and over the tangled mesh using i-TFEM. The vertical displacement at top right corner point for every load step is reported FIG. 36. As illustrated, there is close agreement between the methods applied to the two very-different situations. The deformed configuration for regular and tangled meshes after the last load step are shown in FIG. 37A and FIG. 37b, respectively.

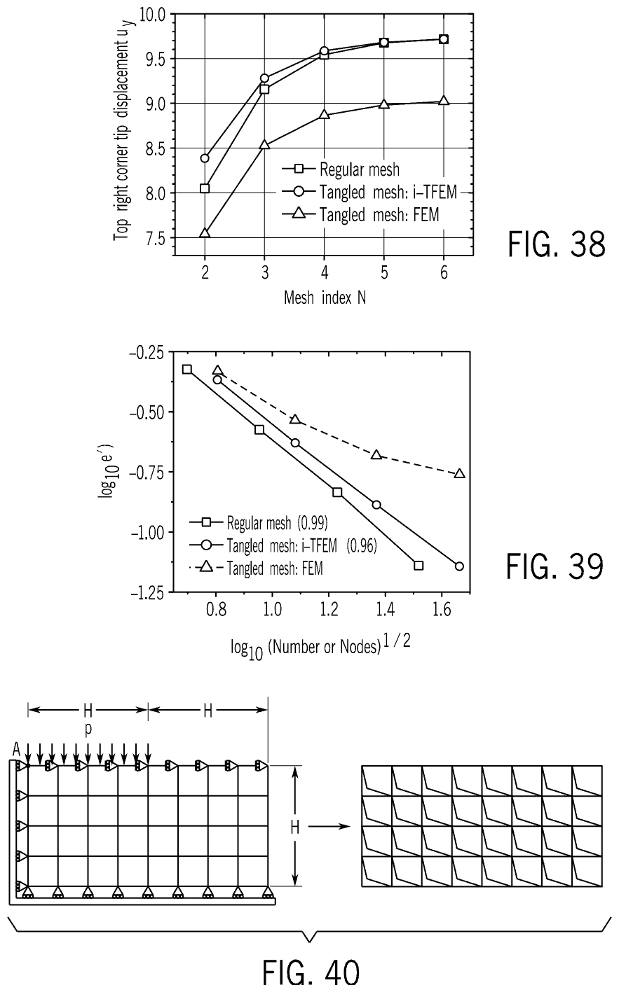

To study convergence, the number of elements was controlled by a mesh-index N, where the number of elements in the regular mesh was 2^{N}×2^{N}. FIG. 35A illustrates the regular mesh when N=3, and FIG. 35B illustrates the corresponding tangled mesh. The solutions from standard FEM over regular mesh, standard FEM over tangled mesh, and i-IFEM over tangled mesh were compared. The vertical displacements at the top right corner point for all three were plotted as a function of N in FIG. 38. Notably, the FEM over a regular mesh and i-TFEM over the tangled mesh converge to (approximately) the same displacement. On the other hand, FEM over a tangled mesh leads to erroneous results.

To study the rate of convergence, we define the displacement error in H₁ error norm as:

$${e}^{h} = \frac{‖ ∇ u - ∇ {u}^{h} ‖}{‖ ∇ u ‖} = {[ {\int }_{Ω} {\vert ∇ u - ∇ {u}^{j} \vert}^{2} d Ω ]}^{0.5} {/ [ {\int }_{Ω} {\vert ∇ u \vert}^{2} d Ω ]}^{0.5} ; \qquad Eq . ( 62 )$$

where u is the reference solution from a fine mesh with N=7, and u^{h} is the solution under consideration. FIG. 39 illustrates the error vs. number of nodes on log-log scale over the untangled mesh, as well as over the tangled mesh using FEM and i-TFEM. A near-optimal convergence rate is found for i-TFEM.

### Punch Problem: Materially Nonlinearity

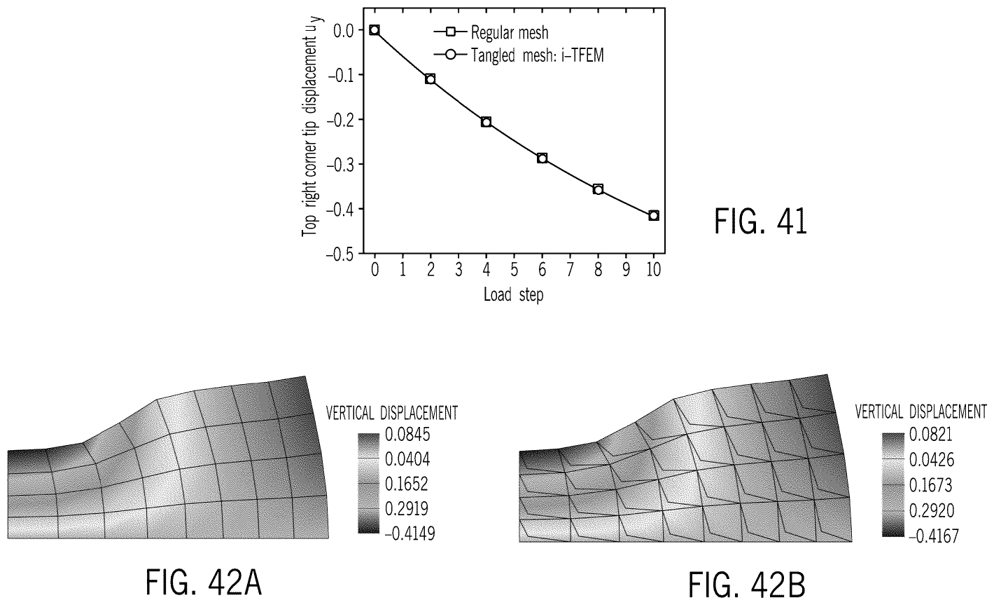

A punch problem was considered with geometric and material nonlinearities. Specifically, a compressible isotropic generalized neo-Hookean material model was considered where the strain energy density is given by:

$${Ψ}_{GNH} ( u ) = \frac{μ}{2} ( {J}_{F}^{- 2 / 3} trb - 3 ) + \frac{K}{2} {( {J}_{F} - 1 )}^{2} ; \qquad Eq . ( 64 )$$

where J_{F}=det F and b=FF^{T} are the left Cauchy-Green deformation tensor, while μ=500 and K=1700 are the material parameters (equivalent to shear and bulk moduli respectively in the small strain limit). A rectangular block is subject to a vertical load p (per unit length) uniformly distributed over top left half of the block where p=1000 and H=1, as illustrated in FIG. 40. The top and left sides of the block are fixed in the horizontal direction, while the bottom is fixed in the vertical direction. To this end, FIG. 41 captures the vertical displacement of a point located at the top left corner for every load step. The results for the regular mesh and tangled mesh (using i-TFEM) match well. For both meshes, the solution converged in about 5 Newton iterations for each load step. On the other hand, standard FEM failed to converge for the tangled mesh. FIG. 42A and FIG. 42B illustrate the deformed configurations for the regular mesh and tangled meshes respectively, after the final load step.

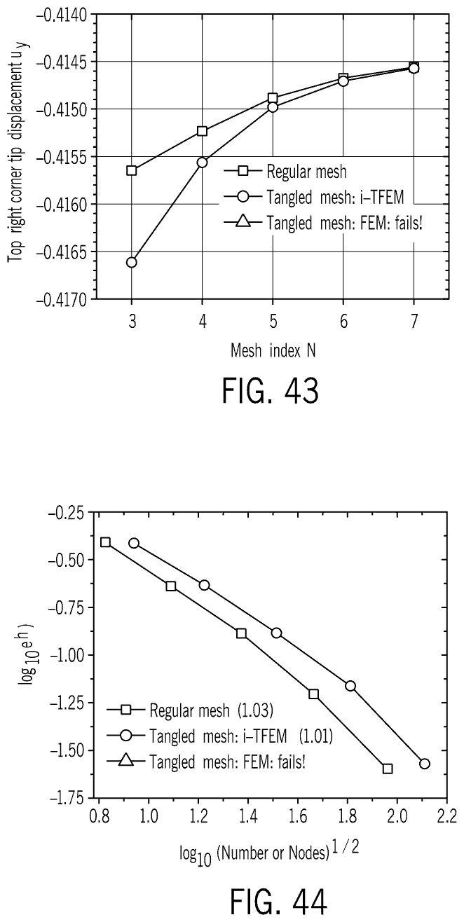

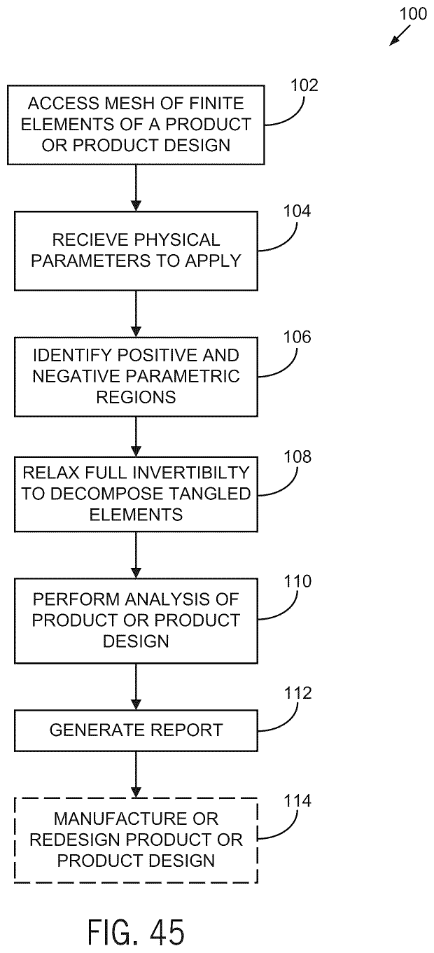

To study the convergence, the mesh index N where the number of elements in the regular mesh is 2^{N+1}×2^{N} was used. The regular and tangled meshes with N=2 are shown in FIG. 40. A convergence study was then carried as N was varied. The vertical displacement u_{y} at point A for the two methods was plotted against the mesh index N, as shown in FIG. 43. It is clear that the two methods converge to the same solution (while standard FEM over the tangled mesh did not converge). Finally, FIG. 44 illustrates the H₁ error over the tangled mesh using i-TFEM and over the regular mesh. The reference solution was obtained with N=7. Once again, i-TFEM exhibited an optimal convergence rate of 1.

### Methods

In one non-limiting example, a method 100 implementing the frameworks and steps described above may begin by accessing (or generating) a mesh of finite elements of a product or product design at process block 102. The mesh may represent or model any physical element, part, or complete product, or may represent or model a product design that has not yet been manufactured or built. At process block 104, a set of physical parameters may be supplied by a user to apply. These steps need not be preformed in this order.

At process block 106, as described above, for elements in the mesh of finite elements, positive and negative parametric regions are identified and, at process block 108, for tangled elements in the mesh of finite elements, a constraint of full invertibility between the positive and negative parametric regions is relaxed to piecewise invertibility to decompose the tangled elements into invertible regions. At process block 110, an analysis of the product or product design can be performed using the mesh of finite elements with the tangled elements decomposed into the invertible regions and the physical parameters. When the analysis is complete, a report is generated at process block 112. As indicated at optional process block 114, he information in the report may be used to manufacture or redesign the product or product design.

### Systems

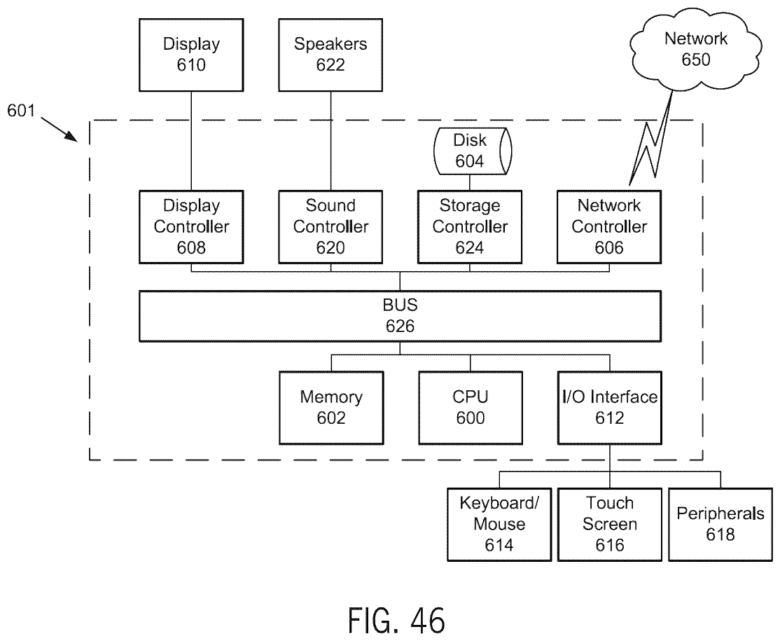

The non-limiting method described above or any process implemented based on the overall disclosure provided herein may be implemented using a computer system. In particular, FIG. 46 is a schematic diagram of one non-limiting example a computer system 200 in accordance with the present disclosure. The computer system 200 may be realized as a desktop computer, a mobile computer, a server, a mobile computing device, and/or may be decentralized as a cloud computing device. That is, though, as will be described, the computer system 200 may include a variety of components, these components may be incorporated into a single physical device, such as a computer, laptop, phone, server, or the like, or may be decentralized and networked or otherwise communicate. Furthermore, thought a variety of components are illustrated and will be described, the computer system may not include all or some of these components.

In the non-limiting example, the computer system 200 may include a processor or “CPU” 202 that is configured to, alone or in combination with other components of the computer system 200, carry out the steps of the processing described above. To do so, the CPU 202 may communicate with a memory 204.

The CPU 202 and memory 204 may communicate directly and/or may be connected through a communications bus 206. The communications bus 206 may provide connections to a variety of other components, including a storage controller 208, to provide access to a disk 210 or other long-term storage. Also, the communications bus 206 may be connected to a network controller 212 that, thereby, connects to a network 214, which may be a local area network, wide area network, intranet, or the internet, or portions thereof. Furthermore, the communications bus 206 may connect to a display controller 216 to then connect to a display 218. The display 18 may be used to communicate, for example, the report described above, or may otherwise be physically printed from a peripheral, as will be described.

The communications bus 206 may connect to a variety of other components, which may further be optional or present only in particular implementations. For example, the communications bus 206 may connect to a sound controller 220 that connects to speakers 222, or an input/output (I/O) interface 226, which can connect to other devices, such as a keyboard/mouse 228, touch screen 230, or other peripherals 232, in addition to these user interfaces.

Therefore, systems and methods are provided where tanging is no longer a constraint. That is, in traditional FEM, quality and tangling are often competing constraints. The systems and methods provided herein remove tanging as a constraint, which can allow for quality to be the focus.

As used herein, the phrase “at least one of A, B, and C” means at least one of A, at least one of B, and/or at least one of C, or any one of A, B, or C or combination of A, B, or C. A, B, and C are elements of a list, and A, B, and C may be anything contained in the Specification.

The present invention has been described in terms of one or more preferred embodiments, and it should be appreciated that many equivalents, alternatives, variations, and modifications, aside from those expressly stated, are possible and within the scope of the invention.

1. A computer system comprising:
a memory storing a mesh of finite elements of a product or product design, wherein the mesh of finite elements include tangles;
an input configured to receive a set of physical parameters to be applied to the product or production design to assess the product or product design;
a processor configured to receive the mesh of finite elements and the set of physical parameters and to carry out steps comprising:
for elements in the mesh of finite elements, identifying positive and negative parametric regions;
for tangled elements in the mesh of finite elements, relaxing a constraint of full invertibility between the positive and negative parametric regions to piecewise invertibility to decompose the tangled elements into invertible regions;
performing an analysis of the product or product design using the mesh of finite elements with the tangled elements decomposed into the invertible regions and the set of physical parameters;
generating a report indicating a performance of the product or product design under the set of physical parameters; and
a display or printer configured to deliver the report to a user.

2. The system of claim 1, wherein the processor is further configured to apply piecewise compatibility conditions to the mesh of finite elements.

3. The system of claim 1, wherein the mesh of finite elements include quadrilateral or hexahedral elements.

4. The system of claim 1, wherein, when the physical parameters include stiffness, only analyzing a parametric region corresponding to a subset of positive Jacobian values.

5. The system of claim 1, wherein the processor is further configured to triangulate a concave region for integration to decompose the tangled elements.

6. The system of claim 1, wherein, if the tangles are removed from the mesh, relaxing a constraint of full invertibility reduces to full invertibility across the mesh of finite elements.

7. The system of claim 1, wherein the mesh of finite elements is a three-dimensional mesh.

8. The system of claim 1, wherein the physical parameters includes at least one of elasticity, thermal, fluid, electromagnetics, or vibration.

9. A method for assessing a product or product design comprising:
receiving a set of physical parameters to be applied to the product or production design;
accessing a mesh of finite elements of a product or product design, wherein the mesh of finite elements include tangles;
for elements in the mesh of finite elements, identifying positive and negative parametric regions;
for tangled elements in the mesh of finite elements, relaxing a constraint of full invertibility between the positive and negative parametric regions to piecewise invertibility to decompose the tangled elements into invertible regions;
performing an analysis of the product or product design using the mesh of finite elements with the tangled elements decomposed into the invertible regions and the set of physical parameters; and
generating a report indicating a performance of the product or product design under the set of physical parameters.

10. The method of claim 9, further comprising manufacturing the product or the product design using information from the report.

11. The method of claim 9, further comprising applying piecewise compatibility conditions to the mesh of finite elements.

12. The method of claim 9, wherein the mesh of finite elements include quadrilateral or hexahedral elements.

13. The method of claim 9, wherein, when the physical parameters include stiffness, only analyzing a parametric region corresponding to a subset of positive Jacobian values.

14. The method of claim 9, wherein decomposing the tangled elements includes triangulating a concave region for integration.

15. The method of claim 9, wherein, if the tangles are removed from the mesh, relaxing a constraint of full invertibility reduces to full invertibility across the mesh of finite elements.

16. The method of claim 9, wherein the mesh of finite elements is a three-dimensional mesh.

17. The method of claim 9, wherein the physical parameters includes at least one of elasticity, thermal, fluid, electromagnetics, or vibration.

18. A non-transitory computer-readable storage medium having instructions stored thereon that, when executed by a computer processor, causes the computer process to carry out a method for analysis of a product or product design including steps comprising:
receiving a set of physical parameters and a mesh of elements of a product or product design, wherein the mesh of elements include tangles;
for elements in the mesh of elements, identifying positive and negative parametric regions;
for tangled elements in the mesh of elements, relaxing a constraint of full invertibility between the positive and negative parametric regions to piecewise invertibility to decompose the tangled elements into invertible regions;
performing an analysis of the product or product design using the mesh of elements with the tangled elements decomposed into the invertible regions and the set of physical parameters; and
generating a report indicating a performance of the product or product design under the set of physical parameters.

19. The storage medium of claim 18, wherein decomposing the tangled elements includes triangulating a concave region for integration.

20. The storage medium of claim 18, further comprising applying piecewise compatibility conditions to the mesh of elements.
